(19) United States
(12) Patent Application Publication
(10) Pub. No.: US 2026/0018401 A1
(43) Pub. Date: Jan. 15, 2026

(54) METHOD AND DEVICE FOR SEPARATION OF EPITAXIAL LAYER FROM NON-CRYSTALLINE SUBSTRATE

(71) Applicant: The Government of the United States of America, as represented by the Secretary of the Navy, ARLINGTON, VA (US)

(72) Inventors: FRANCIS J. KUB, ARNOLD, MD (US); ANDREW D. KOEHLER, ALEXANDRIA, VA (US)

(21) Appl. No.: 19/266,367

(22) Filed: Jul. 11, 2025

Related U.S. Application Data
(60) Provisional application No. 63/670,338, filed on Jul. 12, 2024.
(60) Provisional application No. 63/842,096, filed on Jul. 11, 2025.

(51) Int. Cl. H01L 21/02; H10D 62/85

(52) U.S. Cl. CPC H01L 21/02013; H10D 62/8503

(57) ABSTRACT

A method, wherein a III-nitride-on-engineered substrate is provided. The III-nitride-on-engineered substrate includes a III-nitride epitaxial material. The III-nitride epitaxial material includes a frontside, a backside, and a III-nitride epitaxial region free of grind damage. The III-nitride-on-engineered substrate includes an engineered substrate on the backside of the III-nitride epitaxial material. The engineered substrate includes a non-crystalline substrate. The engineered substrate is removed from the backside of the III-nitride epitaxial material, thereby exposing the III-nitride epitaxial region free of grind damage.

### CROSS-REFERENCE TO RELATED APPLICATIONS

This Application is a Non-provisional of, and claims the benefit of priority under 35 U.S.C. § 119 based on, U.S. Provisional Patent Application No. 63/670,338 filed 12 Jul. 2024 as well as U.S. Provisional Patent Application No. 63/842,096 filed 11 Jul. 2025. The Provisional Applications and all references cited therein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; techtran@nrl.navy.mil, referencing Navy Case No. 212238-US1.

### FIELD OF THE INVENTION

Aspects of the present invention relate generally to semiconductor wafers and, more particularly, to a method and device for separation and transfer of semiconductor epitaxial material from a substrate.

### BACKGROUND OF THE INVENTION

A gallium nitride engineered substrate with a non-crystalline substrate has the attractive features that: large diameter substrates are commercially fabricated, the gallium nitride material has low defect density, and the thick GaN layers can be epitaxially grown on the substrate without cracking.

In U.S. Pat. No. 6,328,796, which is incorporated herein by reference, a GaN engineered substrate is comprised of at least three material layers. The three material layers are a non-crystalline substrate, a single-crystal layer wafer bonded to the non-crystalline substrate, and a single-crystal epitaxial layer grown on the single-crystal layer. In at least one embodiment of the invention, the non-crystalline substrate can be an aluminum nitride ceramic substrate, the single-crystal layer can be a silicon (111) layer or a silicon carbide layer, and the single-crystal epitaxial layer can be a gallium nitride (GaN) epitaxial single-crystal material layer. GaN engineered substrate can be 200 mm and 300 mm diameter.

GaN that is grown on a silicon carbide substrate has high thermal boundary resistance at the interface between GaN and silicon carbide.

### SUMMARY OF THE INVENTION

An embodiment of the invention includes a method to separate and transfer semiconductor epitaxial material, devices fabricated in the semiconductor epitaxial material, or partially fabricated devices in the semiconductor epitaxial material from an engineered substrate comprising a non-crystalline substrate.

An embodiment of the invention includes a method to separate and transfer the III-nitride epitaxial material, devices fabricated in the III-nitride epitaxial material, or partially fabricated devices in the III-nitride epitaxial material from an engineered substrate including a non-crystalline substrate.

Another embodiment of the invention includes a method that in turn includes the following steps. A III-nitride-on-engineered substrate is provided. The III-nitride-on-engineered substrate includes III-nitride epitaxial material. The III-nitride epitaxial layer includes a frontside, a backside, and a III-nitride epitaxial material region free of grind damage. The III-nitride-on-engineered substrate includes an engineered substrate on the backside of the III-nitride epitaxial material. The engineered substrate includes a non-crystalline substrate. The engineered substrate is removed from the backside of the III-nitride epitaxial layer, thereby exposing the III-nitride epitaxial region with the frontside region of the III-nitride epitaxial material free of grind damage.

Another embodiment of the invention includes a device. The device includes a III-nitride epitaxial layer and an engineering substrate abutting the III-nitride epitaxial layer. The engineering substrate includes an AlN nucleation layer abutting the III-nitride epitaxial layer. The engineering substrate also includes a grinding tolerance layer abutting the AlN nucleation layer. The grinding tolerance layer includes a single-crystal growth layer and/or a chemical mechanical polish layer.

Another embodiment of the invention includes a device. The device includes a III-nitride epitaxial layer. The III-nitride epitaxial layer includes an exposed nitrogen polar surface; and a metal polar surface, and a diamond substrate or a silicon carbide substrate permanently bonded, directly or indirectly, to the metal polar surface of the III-nitride epitaxial layer.

An embodiment of the invention includes a method and device to form wafer-scale nitrogen polar III-nitride material bonded to a carrier substrate.

An embodiment of the invention includes an optimized engineered substrate having a grinding tolerance layer.

### BRIEF DESCRIPTION OF THE DRAWINGS

FIG. 1 is a cross-sectional view of a III-nitride-on-engineered substrate starting point for a method according to an embodiment of the invention, wherein the method includes removal of the engineered substrate into an upper region of a non-crystalline substrate.

FIG. 2A is a block diagram of a non-crystalline substrate according to an embodiment of the invention.

FIG. 2B is a block diagram of another non-crystalline substrate according to an embodiment of the invention.

FIG. 3 is a cross-sectional view of a III-nitride-on-engineered substrate starting point for a method according to an embodiment of the invention, wherein the method includes removal of the engineered substrate and into a lower region of the III-nitride epitaxial layer.

FIG. 4A is a block diagram of a chemical mechanical polish material layer according to an embodiment of the invention.

FIG. 4B is a block diagram of another chemical mechanical polish material layer according to an embodiment of the invention.

FIG. 5A is a block diagram of a carrier substrate according to an embodiment of the invention.

FIG. 5B is a block diagram of another carrier substrate according to an embodiment of the invention.

FIG. 6A is a cross-sectional view of an organic attach material tape connecting a carrier substrate and a III-nitride epitaxial layer in a method according to an embodiment of the invention.

FIG. 6B is a cross-sectional view of an inorganic attach material connecting a carrier substrate and a III-nitride epitaxial layer in a method according to an embodiment of the invention.

FIG. 7A is a cross-sectional view of a heat-releasable polymer connecting a carrier substrate and a III-nitride epitaxial layer in a method according to an embodiment of the invention.

FIG. 7B is a cross-sectional view of a UV-releasable polymer connecting a carrier substrate and a III-nitride epitaxial layer in a method according to an embodiment of the invention.

FIG. 8 is a cross-sectional view of a laser-releasable layer and attach material connecting a carrier substrate and a III-nitride epitaxial layer in a method according to an embodiment of the invention.

FIG. 9 is a cross-sectional view of a III-nitride-epitaxial layer at an ending point of a method according to an embodiment of the invention.

FIG. 10 is a cross-sectional view of a III-nitride-epitaxial layer after removal of a carrier substrate and at an ending point of a method according to an embodiment of the invention.

FIG. 11 is a cross-sectional view of an attach material connecting a carrier substrate and a III-nitride epitaxial layer, a conductive mechanical support layer connected to the III-nitride epitaxial layer, a cap material connected to the conductive mechanical support layer, and dicing tape connected to the cap material in a method according to an embodiment of the invention.

FIG. 12 is a cross-sectional view of a phonon bridge matching material layer connected to a III-nitride epitaxial layer, and a silicon surface activation layer connected to the phonon bridge matching material layer wafer bonded to a polycrystalline diamond, single crystal diamond, or silicon carbide substrate in a method according to an embodiment of the invention.

FIG. 13 is a cross-sectional view of a III-nitride-on-engineered substrate starting point for a method according to an embodiment of the invention, wherein the method includes removal of the engineered substrate into at least a lower region of a grinding tolerance layer.

FIG. 14 is a cross-sectional view of a III-nitride-on-engineered substrate starting point for a method according to an embodiment of the invention, wherein the method includes removal of the engineered substrate into at least a lower region of a III-nitride low trap sensitivity layer doped with carbon or iron.

FIG. 15A is a block diagram of a semiconductor low trap sensitivity layer according to an embodiment of the invention.

FIG. 15B is a block diagram of another semiconductor low trap sensitivity layer according to an embodiment of the invention.

FIG. 15C is a block diagram of yet another semiconductor low trap sensitivity layer according to an embodiment of the invention.

FIG. 15D is a block diagram of still another semiconductor low trap sensitivity layer according to an embodiment of the invention.

FIG. 16 is a cross-sectional view of a III-nitride-on-engineered substrate starting point for a method according to an embodiment of the invention, wherein a III-nitride epitaxial material is thick, i.e., having a thickness more than 2 microns, and wherein the method includes removal of the engineered substrate into at least a lower region of the thick III-nitride epitaxial material.

FIG. 17 is a cross-sectional view of a III-nitride epitaxial material attached to a wafer-scale support, optionally prior to removal thereof, and also attached to a remaining region of the III-nitride low trap sensitivity layer doped with carbon or iron.

FIG. 18A is a cross-sectional view of a III-nitride epitaxial layer transferred and temporarily bonded to a dicing tape with the front side support substrate removed after bonding.

FIG. 18B is a cross-sectional view of a III-nitride epitaxial layer transferred and permanently fusion bonded to a diamond substrate with the front side support substrate removed after bonding.

FIG. 18C is a cross-sectional view of a III-nitride epitaxial layer transferred and permanently fusion bonded to a silicon carbide substrate with the front side support substrate removed after bonding.

FIG. 19A is a cross-sectional view of a III-nitride epitaxial layer transferred and permanently fusion bonded to a diamond substrate with the front side support substrate removed after bonding and with phonon bridge material layer at the interface of the carrier substrate and the III-nitride epitaxial material.

FIG. 19B is a cross-sectional view of a III-nitride epitaxial layer transferred and permanently fusion bonded to a silicon carbide substrate with the front side support substrate removed after bonding and with phonon bridge material layer at the interface of the carrier substrate and the III-nitride epitaxial material.

FIG. 20A is a cross-sectional view of a III-nitride epitaxial material having a nitrogen polar surface permanently bonded to a wafer-scale carrier substrate, wherein the carrier substrate includes a diamond substrate.

FIG. 20B is a cross-sectional view of a III-nitride epitaxial material having a nitrogen polar surface permanently bonded to a wafer-scale carrier substrate, wherein the carrier substrate includes a silicon carbide substrate.

FIG. 21A is a cross-sectional view of a III-nitride epitaxial material having a nitrogen polar surface permanently bonded to a wafer-scale carrier substrate and having a phonon bridge material layer at the interface of the carrier substrate and the III-nitride epitaxial material, wherein the carrier substrate includes a diamond substrate.

FIG. 21B is a cross-sectional view of a III-nitride epitaxial material having a nitrogen polar surface permanently bonded to a wafer-scale carrier substrate and having a phonon bridge material layer at the interface of the carrier substrate and the III-nitride epitaxial material, wherein the carrier substrate includes a silicon carbide substrate.

FIG. 22A is a cross-sectional view of a metal-to-metal bond to a metal flange or heat sink.

FIG. 22B is a cross-sectional view of a metal-to-metal bond to a metal on a substrate, metal on a device, or metal on CMOS for heterogeneous integration.

FIG. 23A is a cross-sectional view of a metal-to-metal bond to a metal flange or heat sink with a phonon bridge matching layer at the interface of the III-Nitride epitaxial material and the metal material.

FIG. 23B is a cross-sectional view of a metal-to-metal bond to a metal on a substrate, metal on a device, or metal on CMOS for heterogeneous integration with a phonon bridge matching layer at the interface of the III-Nitride epitaxial material and the metal material.

### DETAILED DESCRIPTION OF THE INVENTION

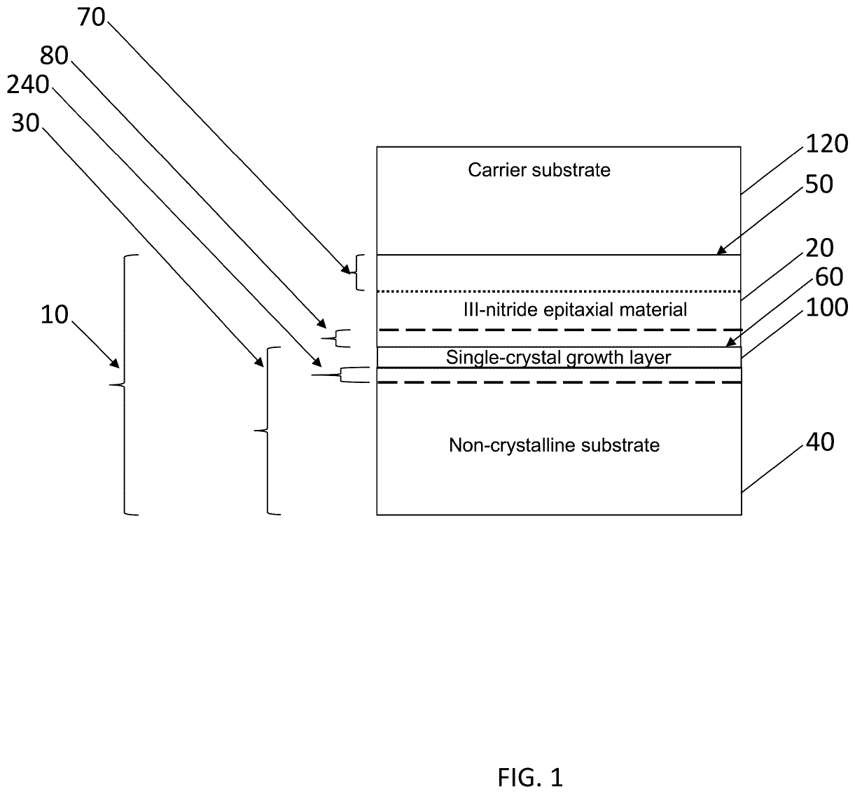

An embodiment of the invention includes a method of manufacturing and/or processing a semiconductor wafer or device. The method is described as follows with reference by way of illustration to FIGS. 1-4. A III-nitride-on-engineered substrate 10 is provided. For the purpose of this patent application, “III-nitride-on-engineered substrate” is a term of art and means a wafer including a single-crystal III-nitride epitaxial material 20 on an engineered substrate 30, the engineered substrate including a non-crystalline substrate 40. Examples of the III-nitride epitaxial material include GaN, AlGaN, AlN, AlInN, AlScN, etc. In an embodiment of the invention, the III-nitride material 20 includes one or more III-nitride epitaxial layers. In embodiments of the invention, the III-nitride epitaxial material has a metal polar front surface 50, a nitrogen polar back surface 60, and III-nitride material is hexagonal C-axis material. Dimensions, e.g., widths and thicknesses, shown in the figures are intended for ease of viewing and are not intended to be proportional to practical components of the III-nitride-on-engineered substrate 10. In an embodiment of the invention, the III-nitride epitaxial material 20 has a thickness in the range of approximately 0.3 microns to 100 microns. For the purpose of this patent application, “engineered substrate” is a term of art and means a substrate composite including one or more standard layer and/or one or more standard barrier layers. At least one example of an engineered substrate 30 and methods of manufacture thereof usable in a III-nitride-on-engineered substrate consistent with an embodiment of the invention is found, for example, in U.S. Pat. No. 6,323,108 to Kub et al., which is incorporated herein by reference. The III-nitride-on-engineered substrate 10 includes a III-nitride epitaxial material 20. The III-nitride epitaxial layer includes a frontside 50, a backside 60, and a III-nitride epitaxial region free of grind damage 70. In an embodiment of the invention, the III-nitride epitaxial region free of grind damage 70 has a thickness in the range between approximately 0.2 microns and approximately 200 microns. In embodiments of the invention, the III-nitride epitaxial material has a metal polar front surface 50, a nitrogen polar back surface 60, and III-nitride epitaxial material is hexagonal C-axis material. For the purposes of this patent application, “free of grind damage” is a term of art and means that the grind damage free III-nitride epitaxial region has a subsurface defect density (“SSD”) less than 1×10⁴ cm⁻² or subsurface crack (“SSC”) density less than 1×10⁴ cm⁻². The III-nitride-on-engineered substrate 10 includes an engineered substrate 30 on the backside 60 of the III-nitride epitaxial layer. In at least one embodiment of the invention, the engineered substrate 30 includes a standard, non-crystalline substrate 40. In an embodiment of the invention, the III-nitride epitaxial material 20 includes one or more standard device dies. For example, a semiconductor wafer having a diameter greater than 200 mm includes the III-nitride-on-engineered substrate 10. At least the engineered substrate 30 is removed from the backside 60 of the III-nitride epitaxial material 20, thereby exposing the III-nitride epitaxial material 20, which includes a III-nitride epitaxial region free of grind damage 70. In other words, in an embodiment of the invention, beyond the engineered substrate 30, at least a portion of the III-nitride epitaxial layer is removed as well. FIG. 1 conceptually shows III-nitride epitaxial region free of grind damage 70 as the region above the dotted line in the III-nitride epitaxial material 20. The III-nitride epitaxial region free of grind damage, for example, has a thickness in the range of 100 nm to 99.9 microns. In an embodiment of the invention, the process of removing the engineered substrate from the backside of the III-nitride epitaxial layer optionally includes removal of a portion 80 of the III-nitride epitaxial layer that exhibits grind damage. In another embodiment of the invention, the engineered substrate includes a standard, semiconductor low trap sensitivity region doped with iron or carbon with minority carrier lifetime less than 1 nanosecond, the semiconductor low trap sensitivity region exhibits grind damage, and the process of removing the engineered substrate from the backside of the III-nitride epitaxial layer optionally includes or does not include removal of this grind-damaged, semiconductor low trap sensitivity region. One of ordinary skill in the art will readily appreciate that, preferably, for a device fabricated on the frontside region of the III-nitride epitaxial material, such as lateral transistors or light emitters, the frontside region is preferably free of grind damage in practicing an embodiment of the invention. One of ordinary skill in the art will readily appreciate that, for device that employ the entire thickness of the III-nitride epitaxial layer such as vertical power switches, preferably, as little of the III-nitride epitaxial layer as possible exhibits grind damage in practicing an embodiment of the invention. In the figures, one or more heavy, dashed lines indicate illustrative level to which a layer is optionally ground in a standard manner, in an embodiment of the invention. In at least one embodiment of the invention, the process of grinding includes standard rough grinding, standard fine grinding, standard nanogrinding, and standard low damage grinding. Low damage grinding processes include methods such as ultrasonic vibration assisted grinding (“UVAG”), ultrasonic vibration assisted nanogrinding, and elliptic vibration assisted grinding. Standard processes such as Chemical Mechanical Polishing, polishing with a dry pad, plasma etching, chemical etching, or ion milling are optionally used, after the rough grinding, fine grinding, and low damage grinding processes to remove portions of the engineered substrate 30 or the Subsurface Defects and Subsurface Cracks that extend into the III-nitride epitaxial layer closer to the surface of the III-nitride epitaxial layer beyond the material removed by grinding, fine grinding and low damage grinding. In at least one embodiment of the invention, the fine grinding and low damage grinding process results in SSD or SSC that extend less than 5 microns into the III-nitride epitaxial layer. In at least one embodiment of the invention, the fine grinding and low damage grinding process results in SSD or SSC that extend less than 1 microns into the III-nitride epitaxial layer. In at least one embodiment of the invention, the fine grinding and low damage grinding process results in SSD or SSC that extend less than 300 nm into the III-nitride epitaxial layer.

Optionally, the III-nitride epitaxial material 20 and the engineered substrate 30 are thermally expansion matched, and the III-nitride epitaxial layer is free of cracks. In an embodiment of the invention, the engineered substrate 30 includes, for example, non-crystalline aluminum nitride (AlN) or non-crystalline silicon carbide (SiC). Optionally, the III-nitride epitaxial material 20 includes a threading dislocation density less than 10⁹ cm⁻².

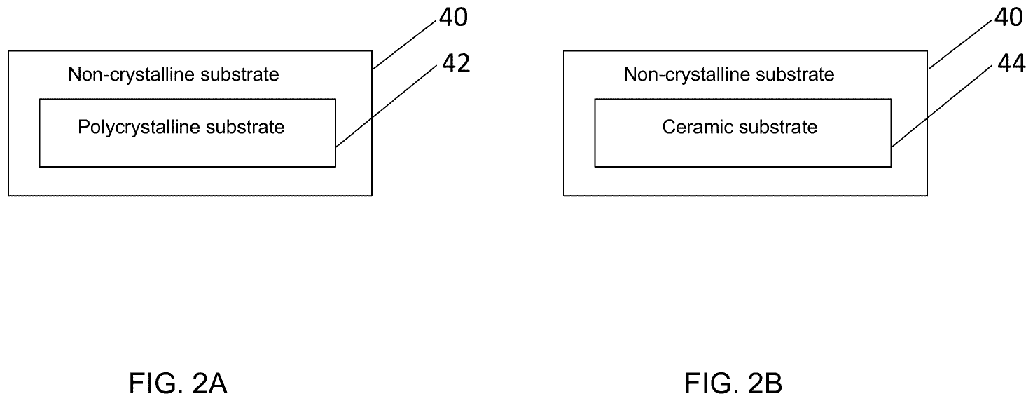

Optionally, the non-crystalline substrate 40 comprises a standard, polycrystalline substrate 42 or a standard, ceramic substrate 44, as shown by way of illustration in FIGS. 2A and 2B.

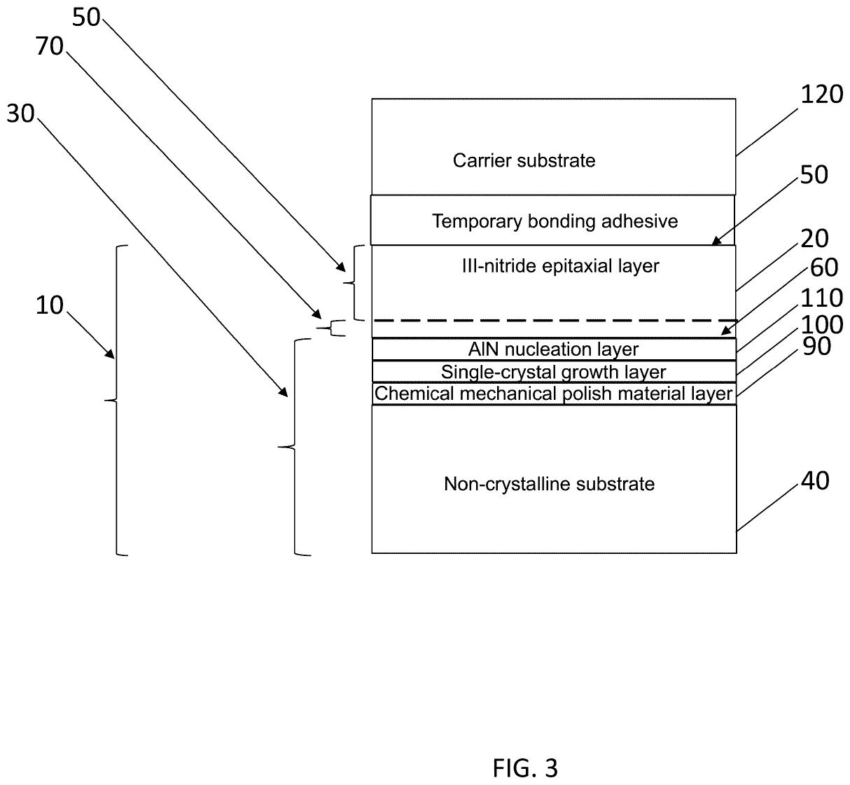

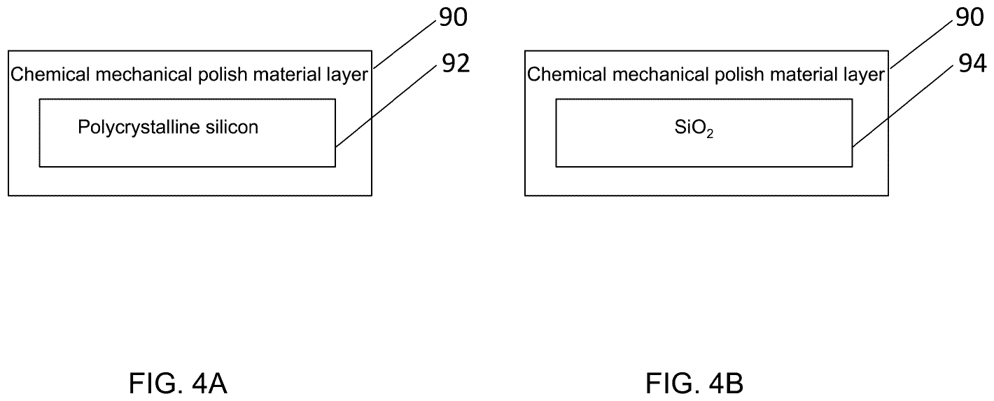

Optionally, the removing, from the backside 60 of the III-nitride epitaxial material 20, the engineered substrate is effected by processes, such as: wafer-scale grinding, wafer-scale Chemical Mechanical Polishing (“CMP”), wafer-scale plasma etching, wafer-scale chemical etching the engineered substrate 30; and/or subsequently wafer-scale chemical mechanical polishing, wafer-scale plasma etching, or wafer-scale chemical etching the engineered substrate 30 or portions of the III-nitride epitaxial material 20. Optionally, the engineered substrate 30 includes a standard, chemical mechanical polish material layer 90 abutting the non-crystalline substrate 40, as shown by way of illustration in FIG. 3. The chemical mechanical polish material layer 90 optionally includes polycrystalline silicon 92 or silicon oxide SiO₂ 94, as shown by way of illustration in FIGS. 4A and 4B. The engineered substrate further includes a standard, single-crystal, growth layer 100 abutting the chemical mechanical polish material layer 90. The single-crystal, growth layer 100, for example, includes a standard, single-crystal silicon (111) growth layer or single-crystal silicon carbide (SiC) growth layer abutting the chemical mechanical polish material layer 90. In at least one embodiment of the invention, the single-crystal SiC layer has a silicon face (0001) orientation with zero degree offset. The single-crystal growth layer enables the growth of single-crystal III-nitride epitaxial material. The chemical mechanical polish material layer 90 is CMP polished to a surface roughness less than 1 nm RMS, and the single-crystal growth layer 100 is fusion wafer bonded to the surface of the chemical mechanical polish layer 90 and thinned using hydrogen ion splitting (“Smart Cut”) followed by CMP polishing or wafer bonding of single-crystal material and etch back. The III-nitride epitaxial material 20 also includes a standard, AlN nucleation layer 110 abutting the single-crystal growth layer 100 and the III-nitride epitaxial material 20.

### Polyimide Support Material on the Front Side

In at least one embodiment of the invention, a standard, polyimide material layer with a thickness in the range of 1 to 20 microns is optionally deposited on the front surface of the III-nitride dies, or wafer scale III-nitride material, prior to attaching the carrier substrate to provide mechanical support.

### Carrier Substrate Support on Front Side of III-Nitride Epitaxial Layer

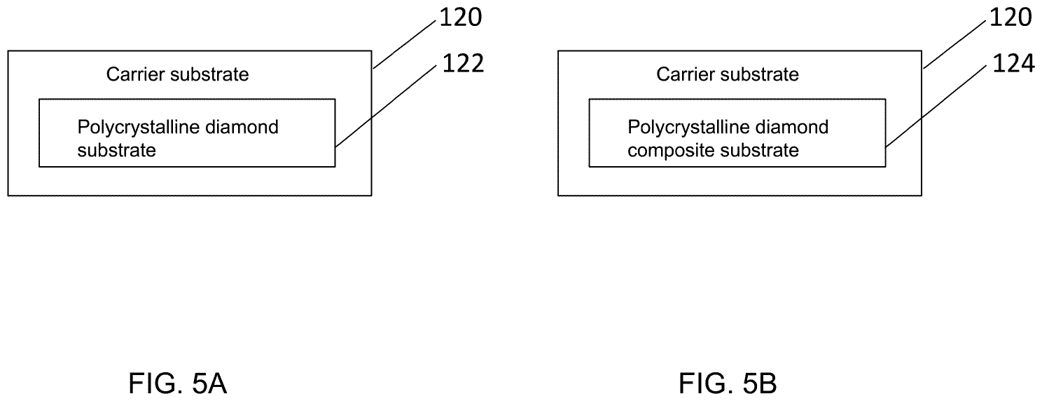

Optionally, the III-nitride epitaxial material 20 is attached or bonded to a standard carrier substrate 120, optionally with a Total Thickness Variation (“TTV”) less than 2 microns. In at least one embodiment, the carrier substrate is a permanently bonded substrate (i.e., a handle substrate). In at least one embodiment, the carrier substrate is a temporarily bonded substrate. In at least one embodiment of the invention, the exposed surface of the III-nitride epitaxial material 60 is optionally CMP polished to a surface roughness less than 1 nm rms. In at least one embodiment of the invention, the exposed surface of the III-nitride epitaxial material 60 is optionally CMP polished to a surface roughness less than 1 nm rms and a phonon bridge material layer is deposited on the surface of the CMP polished III-nitride material layer. For the purpose of this patent application, “phonon bridge” is a term of art and means a material layer or mechanism that facilitates efficient phonon transport across interfaces or through heterogeneous materials. The phonon bridge material reduces thermal boundary resistance (“TBR”), which is the resistance to heat flow at the interface between two materials. The phonon bridge material, for example, includes material layers such as boron carbide, AlGaN, and other standard material. Optionally, the III-nitride epitaxial material 20 is temporary bonded or permanently bonded to a standard carrier substrate 120. The permanent bond may be a surface activated bond (SAB), a plasma activated bond, a vacuum bond, a fusion bond, a metal bond, a spin-on glass bond, a HSQ bond, or an organic bond. In at least one embodiment of the invention, the carrier substrate 120 includes a standard glass, quartz, or silicon substrate for temporary bonding to the III-nitride epitaxial material 20. In at least one embodiment of the invention, the carrier substrate 120 includes a standard, silicon carbide substrate; a standard, sapphire substrate; a standard, silicon substrate; a standard, glass substrate; or a standard, polymer substrate for permanent bond to the III-nitride epitaxial material 20. In at least one embodiment of the invention, the carrier substrate includes a standard, polycrystalline diamond substrate 122 or a standard, polycrystalline diamond composite substrate 124, as shown by way of illustration in FIGS. 5A and 5B. In at least one embodiment of the invention, the carrier substrate optionally includes a silicon, a silicon carbide, polycrystalline diamond, a diamond composite, a single-crystal diamond, a sapphire, a polymer, or a foil substrate permanently bonded to the III-nitride epitaxial material 20. In at least one embodiment of the invention, the carrier substrate optionally includes a silicon substrate with a resistivity more than 1000 ohm-cm or a silicon carbide, polycrystalline diamond, a single-crystal diamond, a diamond composite, or a sapphire substrate with a resistivity more than 10,000 ohm-cm. In at least one embodiment of the invention, a polymer or foil substrate permanently bonded to the III-nitride epitaxial material enables flexible III-nitride epitaxial material. For the purpose of this patent application, “carrier substrate” is synonymous with “wafer carrier,” “wafer support,” “wafer-scale support,” and “wafer support carrier.” A frontside of the III-nitride epitaxial layer is supported using the carrier substrate. For example, the III-nitride epitaxial layer is attached to the carrier substrate via a standard temporary bond or a standard permanent bond, the engineered substrate is removed and optionally a portion of the III-nitride epitaxial material is removed.

### Attaching to a Carrier Substrate to Organic or Inorganic Attach Material

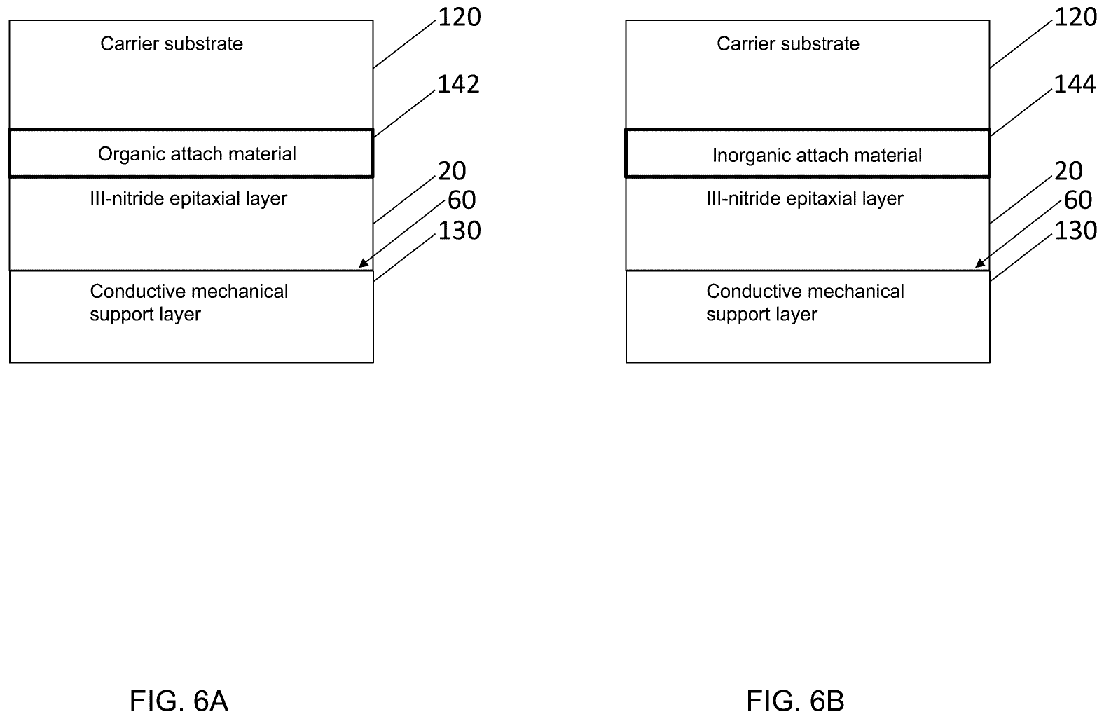

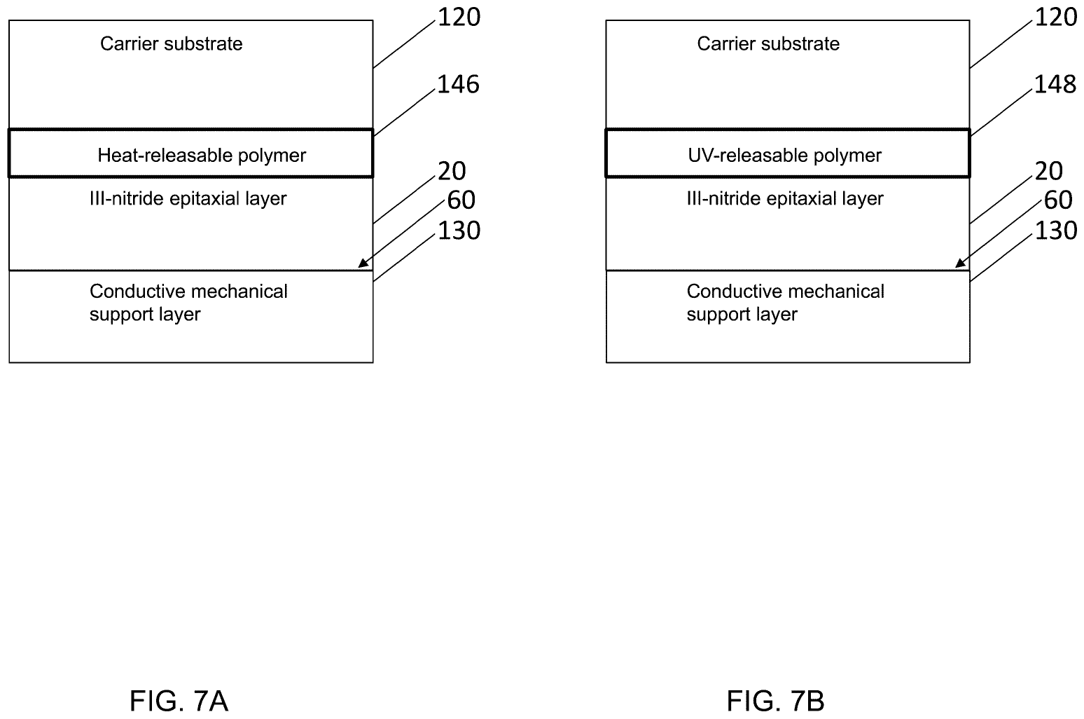

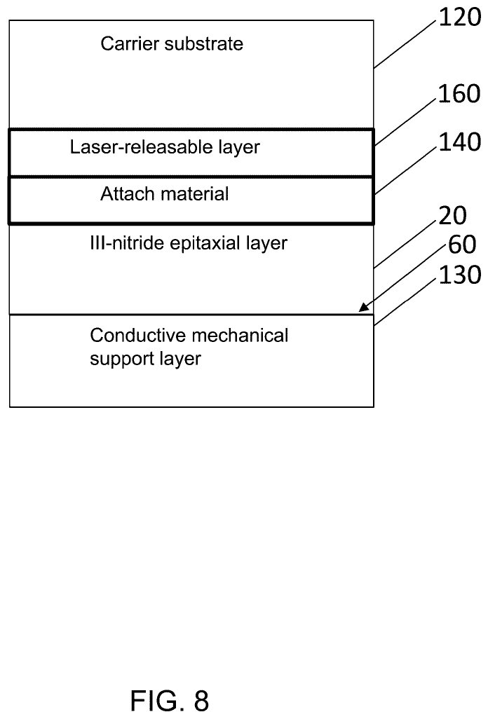

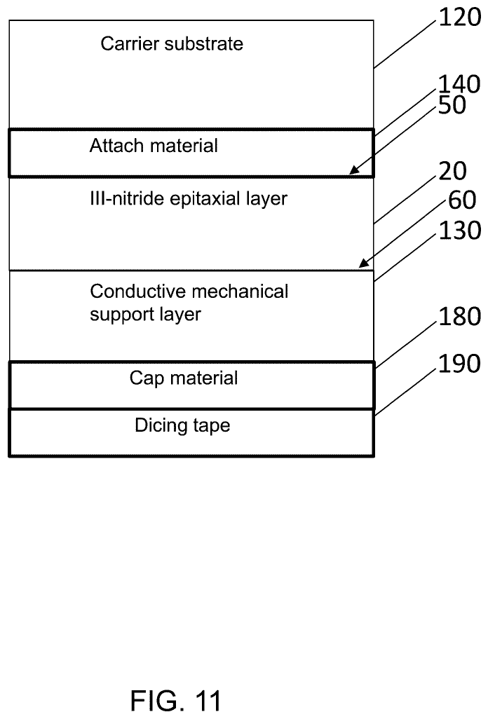

Optionally, the attaching the III-nitride epitaxial material 20 to the carrier substrate 120 includes one or more of the following steps. The III-nitride epitaxial material 20 is temporary bonded or permanent bonded in a standard manner to the carrier substrate 120. The III-nitride epitaxial material 20 may be attached to the carrier substrate 120 using a standard, attach material. The attach material 140, for example, includes a standard, organic attach material 142, as shown by way of illustration in FIG. 6A, or a standard, inorganic attach material 144, as shown by way of illustration in FIG. 6B. In at least one embodiment of the invention, the attach material 140 a standard, heat-releasable polymer 146 or standard, UV-releasable polymer 148, as shown by way of illustration in FIGS. 7A and 7B. In at least one embodiment of the invention, the III-nitride epitaxial material is optionally attached to the carrier substrate using a standard, Laser Release Layer (“LRL”) 160, or a combination of a standard, organic attach material or a standard, inorganic attach material and a LRL as shown by way of illustration in FIG. 8. The LRL is optionally also an organic material or inorganic material. The inorganic LRL optionally includes hydrogenated amorphous silicon. The LRL optionally includes a standard, laser release polymer. In at least one embodiment, the attach material optionally includes two material layers with the LRL abutting the transparent carrier substrate. The laser wavelengths may be infrared wavelengths, visible wavelengths, or ultraviolet wavelengths. The III-nitride epitaxial layer is attached to the carrier substrate using the attach material 140, as shown by way of illustration in FIGS. 8 and 11.

The engineered substrate 30 is wafer-scale removed using multiple, process steps including rough grinding, fine grinding, CMP, plasma etching, chemical etching or ion milling. These embodiments for removing the engineered substrate, 30, include the use of a grinding tolerance layer 220 formed within the engineer substrate 30, grinding into the top region of the non-crystalline substrate 40, grinding into a low trap sensitivity layer 230 formed within the III-nitride epitaxial material 20, or grinding into a III-nitride epitaxial material 20 with a thickness more than two microns in an embodiment, a thickness more than four microns in an embodiment, more than eight microns in an embodiment, a thickness more than 15 microns in an embodiment, or more a thickness than 30 microns in an embodiment.

Optionally, the method after removing the engineered substrate 30 further includes the following steps. Three illustrative embodiments of the invention are discussed as follows, and from the discussion one of ordinary skill in the art will readily appreciate other and equally feasible embodiments of the invention. A first embodiment of the invention includes wafer-scale bonding the III-nitride epitaxial material to a polycrystalline diamond, a single-crystal diamond, a silicon substrate, a sapphire substrate, or a silicon carbide substrate. The back surface of the III-nitride epitaxial material is CMP polished to a surface roughness less than 1 nm while attached to the carrier support, a phonon bridge layer is deposited, and the back surface of the III-nitride epitaxial material is permanently wafer bonded to a polycrystalline diamond, a single-crystal diamond, a silicon substrate, a sapphire substrate, or a silicon carbide substrate. The permanent bond may be a surface activated bond (SAB), a plasma activated bond, a vacuum bond, a fusion bond, a metal bond, a spin-on glass bond, a HSQ bond, or an organic bond. The bonded wafer may be singulated after forming the wafer-to-wafer bond. The method of singulating the die includes standard plasma dicing, standard sawing, or standard laser cutting.

A second embodiment of the invention includes forming a conductive metal support layer on the backside of the III-nitride epitaxial layer, wafer scale removing the metal or seed metal from the kerf lanes or not forming thick metal in the kerf lanes, wafer-scale transferring the metal surface to a dicing tape, optionally deposit an organic protection material, singulate, optionally flip the die within the die-to-die tool, die-to-wafer tool, or microprint transfer tool and optionally pick and place the Known Good Die (“KGD”) and transfer to on a tape frame to optionally remove the organic protection material, to be cleaned and optionally plasma activated, optionally flip the die within the die-to-die or die-to-wafer tool, and then die-to-die or die-wafer solder bond, thermocompression bond, fusion bond, or hybrid bond to a metal surface on a second substrate or to a surface on the second substrate, and optionally remove a polyimide mechanical support layer if present. The method of singulating die include standard plasma dicing, standard sawing, or standard laser cutting.

A third embodiment of the invention includes forming a conductive metal support layer on the backside of the III-nitride epitaxial layer, wafer scale removing the metal or seed metal from the kerf lanes or not forming thick metal in the kerf lanes while attached to the carrier substrate, optionally deposit an organic protection material, singulate while attached to the carrier substrate, selectively illuminate the LRL through a transparent carrier substrate to partially decompose the LRL to reduce the adhesive strength in selected lateral regions, pick the III-nitride epitaxial material or device die from the carrier substrate 120 optionally using a process of flipping the die within the die-to-die tool, die-to-wafer tool, or microprint transfer tool, and optionally pick and place the Known Good Die (“KGD”) on a tape frame to be cleaned and optionally plasma activated, optionally flip the die within the die-to-die or die-to-wafer tool, and then die-to-die or die-wafer solder bond, thermocompression bond, fusion bond, hybrid bond, van der Waal bond, or adhesive bond to a metal surface on a second substrate or the surface of a second substrate, and optionally remove a polyimide mechanical support layer if present. The method of singulating die include standard plasma dicing, standard sawing, or standard laser cutting.

The print transfer tool uses a stamp to mechanically support the III-nitride epitaxial die during transfer. The print transfer tool does not require the uses of polyimide on the front side of the die or conductive metal on the backside of the die to mechanically support the III-nitride epitaxial die material during transfer and bonding.

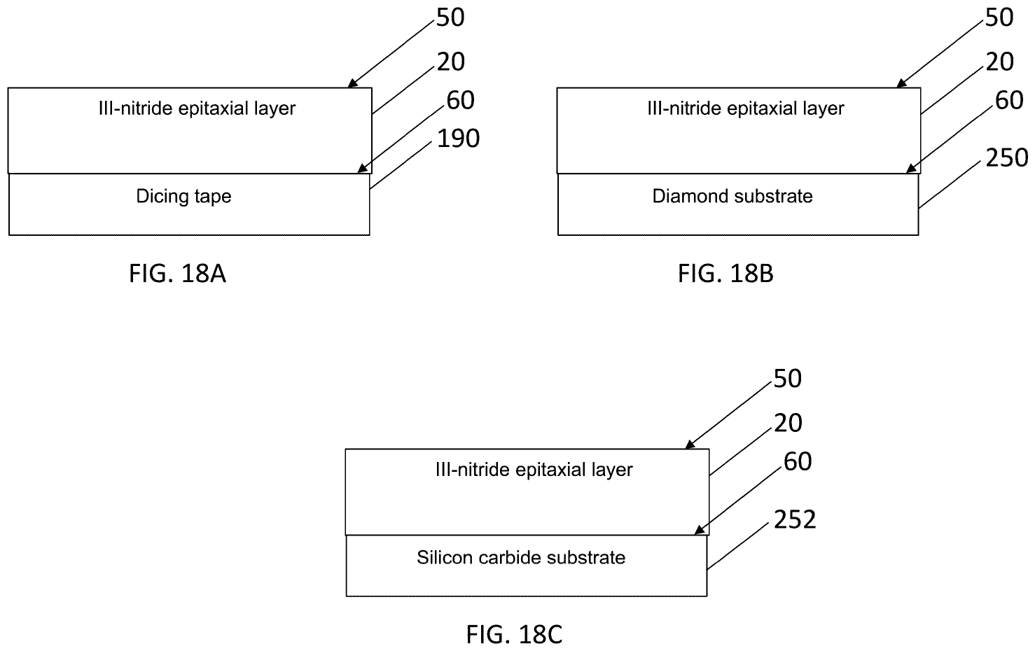

Optionally, a standard cap material 180 is deposited on the conductive mechanical support metal layer 130, as shown by way of illustration in FIG. 11. A standard, dicing tape 190 is attached directly to the conductive mechanical support metal layer 130 or indirectly thereto via the cap material 180, as shown by way of illustration in FIGS. 11 and 18A. The passivation metal layer 180, for example, includes NiCu, Pd, Ti, or Sn. The cap layer facilitates thermocompression or fusion bonding by reducing the oxidation of copper. In at least one embodiment, the conductive mechanical support metal 130 is solder bonded, thermocompression bonding, fusion bonded, or hybrid bonded to a metal layer or device having a metal or solder surface on a second substrate.

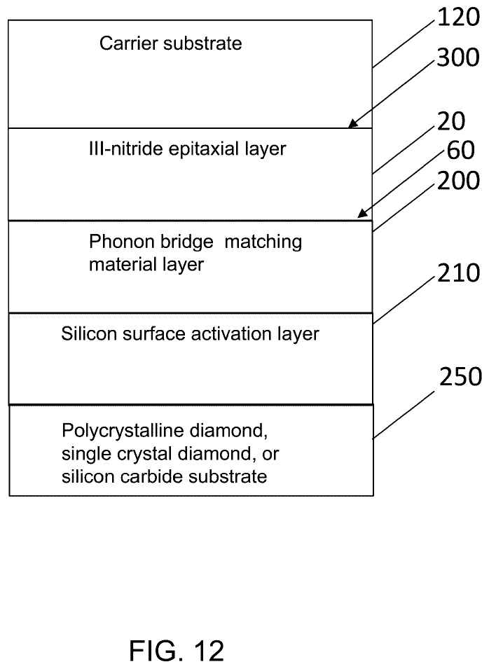

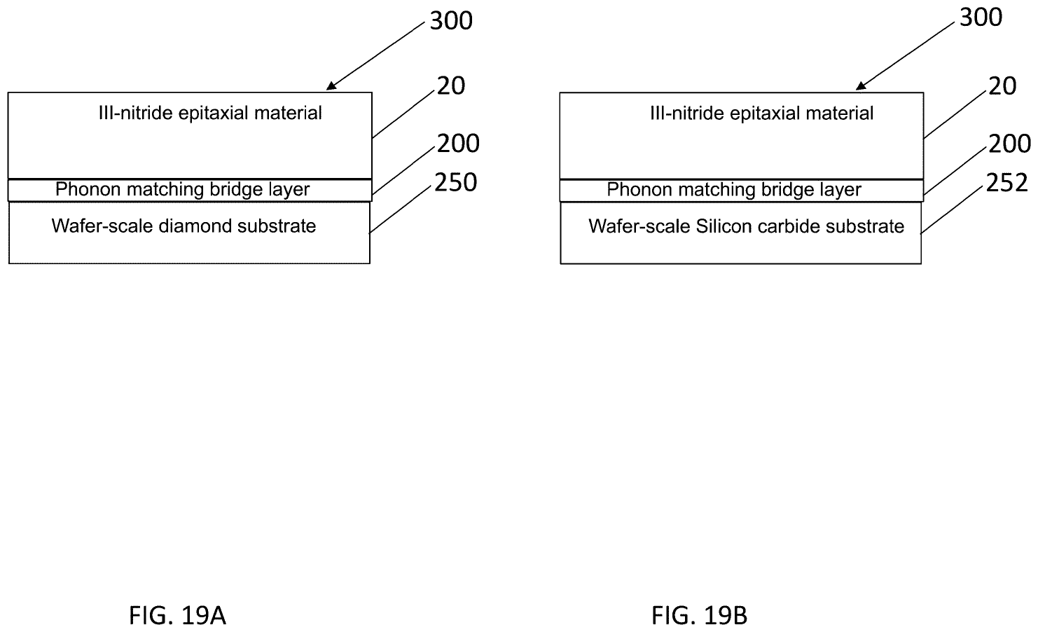

In at least one embodiment, the back surface of the III-nitride material is CMP polished to a surface roughness of less than 1 nm rms while attached to the carrier substrate. The back surface of the III-nitride epitaxial material 20 is fusion wafer bonded to a polycrystalline diamond substrate, single crystal diamond substrate, or a silicon substrate, a sapphire substrate, a silicon carbide substrate 250, as shown by illustration in FIG. 12, producing III-nitride epitaxial material wafer bonded to a diamond or silicon carbide substrate 250 with a low thermal boundary resistance at the interface with a standard gallium polar surface 300 available for device processing after removal of the carrier substrate 120. For example, the metal polar surface 300 of the III-nitride epitaxial material includes a gallium polar surface, as shown by way of illustration in FIGS. 19A and 19B.

Optionally, the method further includes the following steps. The back surface of the III-nitride layer is CMP polished to a surface roughness of less than 1 nm. A standard, phonon bridge matching material layer 200 is optionally wafer-scale deposited on the backside of the III-nitride epitaxial material 20 or on the front surface of the substrate 250 or 252, as shown by way of illustration in FIGS. 12, 19A, and 19B. A standard, silicon surface activation layer or metal activation layer 210 is optionally deposited on the substrate 250 or 252, and a standard plasma activation is performed activating the silicon surface activation layer to facilitate wafer bonding. In at least one embodiment, the polycrystalline diamond or single crystal diamond substrate 252 is exposed to a NH₃/H₂O₂ solution to activate the surface for wafer bonding without the use of the silicon surface activation layer. The wafer bonding may be performed in a vacuum. The substrate 250 and 252 may have a resistivity more than 10,000 ohm-cm.

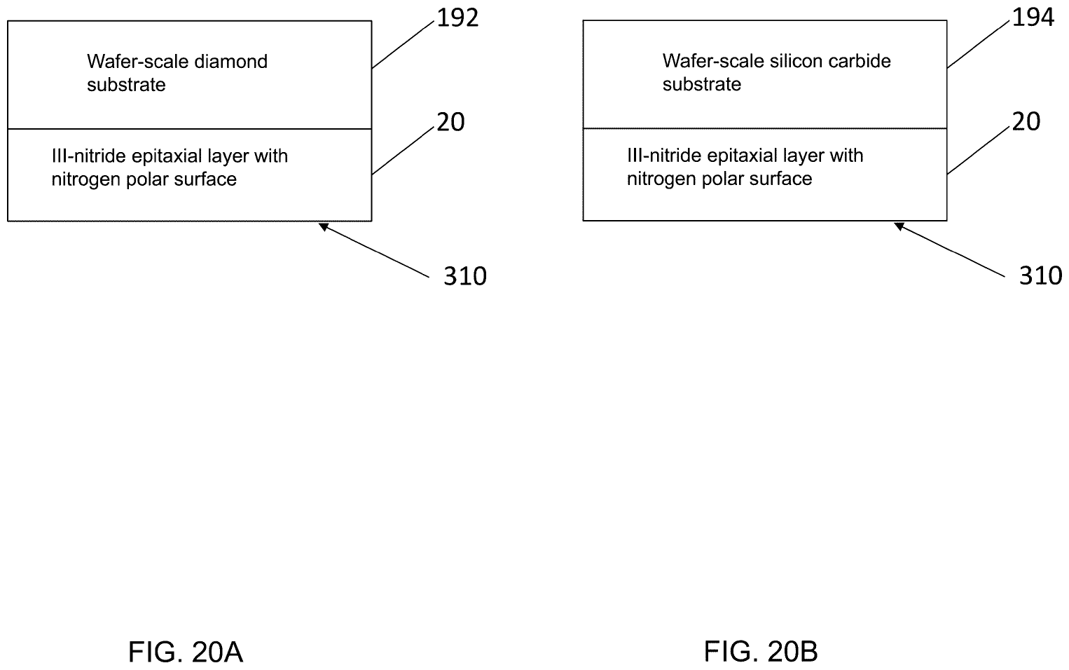

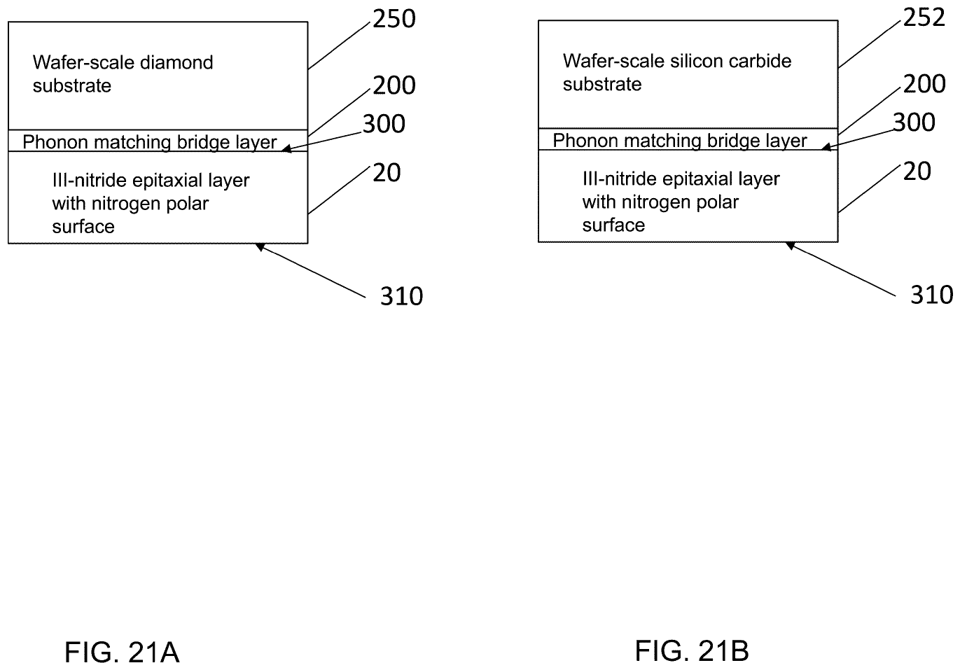

In at least one embodiment, the metal polar surface 50 of the III-nitride epitaxial material 30 may be CMP polished to have a surface roughness less than 1 nm may be permanently wafer-scale bonded to a carrier substrate comprising a silicon carbide substrate, a silicon substrate, a sapphire substrate, a polycrystalline diamond substrate, or a single crystal diamond substrate as shown in FIG. 1. In further processing, the engineering substrate 20 is removed and the exposed nitrogen polar surface 310 CMP polished producing an exposed nitrogen polar surface 310 available for further III-nitride epitaxial growth material and device processing, as shown by way of illustration in FIGS. 20A, 20B, and 21. The further III-nitride epitaxial growth material will be free of grind damage. Optionally, the silicon surface activation layer or metal activation 210 is deposited on a polycrystalline diamond substrate 250 or silicon carbide substrate 252. The silicon carbide substrate and polycrystalline diamond substrate, for example, has a less than 1 nm rms surface roughness. In at least one embodiment, the polycrystalline diamond or single crystal diamond substrate 252 is exposed to a NH₃/H₂O₂ solution to activate the surface for wafer bonding without the use of the silicon surface activation layer.

Concerning the nitrogen polar surface, in an embodiment of the invention, the gallium polar surface is permanently bonded to a carrier support substrate (e.g., a silicon carbide substrate, a silicon substrate, a sapphire substrate, a polycrystalline diamond substrate, or a diamond substrate).

Concerning the nitrogen polar surface, in another embodiment of the invention, the substrate is flipped in a wafer bonding tool. After removing the engineered substrate, the nitrogen polar surface is exposed. The wafer bonding tool supports the nitrogen polar surface. The temporary bonded metal polar surface is removed from the carrier substrate. The gallium polar surface is fusion bonded to a silicon carbide substrate, a silicon substrate, a sapphire substrate, polycrystalline diamond, or single-crystal diamond substrate. Optionally, an exposed metal polar surface is bonded to the silicon carbide substrate, a silicon substrate, a sapphire substrate, the diamond substrate, or the polycrystalline diamond with a phonon bridge layer at the interface.

In at least one embodiment, the metal polar surface 50 of the III-nitride epitaxial material 30 may be CMP polished to have a surface roughness less than 1 nm rms. The metal polar surface 50 of the III-nitride epitaxial material is temporarily bonded to a carrier substrate as shown in FIG. 1 and the engineering substrate and aluminum nitride nucleation layer is removed producing an exposed nitrogen polar surface of the III-nitride epitaxial material. In an embodiment of the invention, aluminum nitride nucleation layer may not be removed. In an embodiment of the invention, the III-nitride epitaxial material may be a buffer free embodiment with an aluminum nitride layer, a III-nitride channel layer, and a III-nitride barrier layer. The aluminum nitride nucleation layer necessary for the buffer free transistor operation. The III-nitride epitaxial material on a carrier substrate can be flipped within the wafer bonding tool or a module connected to the wafer bonding tool, which entails temporarily bonding the exposed nitrogen polar surface 310 to a carrier substrate and removing the carrier substrate from the metal polar surface 300 of the III-nitride epitaxial material in FIG. 21. The metal polar surface 300 of the III-nitride epitaxial material can be cleaned and plasma activated within modules in the wafer bonding tool and the metal polar surface 300 of the III-nitride epitaxial layer wafer bonded to the substrate 250 or substrate 252. The carrier substrate on the nitrogen polar surface 310 is removed and the nitrogen polar surface 310 cleaned. The nitrogen polar surface 310 may be CMP polished producing an exposed nitrogen polar surface 310 available for further III-nitride epitaxial growth and device processing, as shown by way of illustration in FIG. 21. The further III-nitride epitaxial growth material will be free of grind damage. Optionally, the silicon surface activation layer or metal activation 210 is deposited on a polycrystalline diamond substrate 250 or silicon carbide substrate 252. The silicon carbide substrate, a silicon substrate, a sapphire substrate, and polycrystalline diamond substrate, for example, has a less than 1 nm rms surface roughness. In at least one embodiment, the polycrystalline diamond or single crystal diamond substrate 252 is exposed to a NH₃/H₂O₂ solution to activate the surface for wafer bonding without the use of the silicon surface activation layer.

### Conductive Mechanical Support Metal

An optional standard, phonon bridge matching material layer 200 is deposited on the backside of the III-nitride epitaxial material 20, to improve thermal transport from the III-nitride epitaxial material into a conductive mechanical support metal, such as shown by way of illustration in FIGS. 19A-19B. For the purpose of this patent application, “phonon bridge” is a term of art and means a material layer or mechanism that facilitates efficient phonon transport across interfaces or through heterogeneous materials. The phonon bridge material reduces thermal boundary resistance (“TBR”), which is the resistance to heat flow at the interface between two materials. The phonon bridge material 200, for example, includes material layers such as boron carbide, AlGaN, and other standard material.

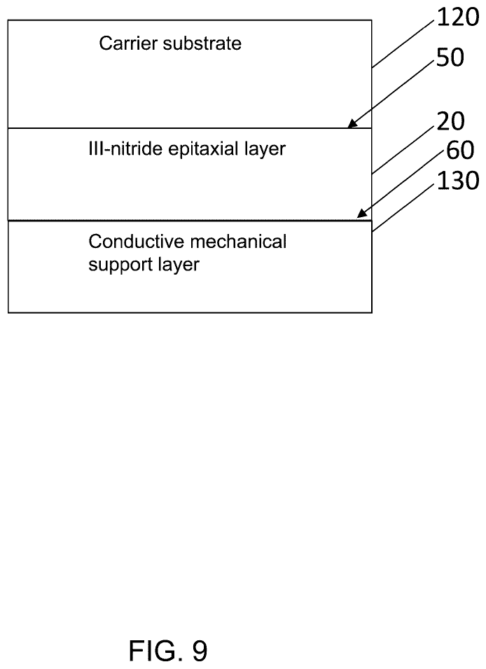

In at least one embodiment of the invention, a standard, conductive mechanical support metal layer 130 is optionally deposited or electroplated on the backside of the III-nitride epitaxial layer, as shown by way of illustration in FIG. 9. For example, the conductive mechanical support metal layer including gold, copper and/or molybdenum. In at least one embodiment of the invention, an optional adhesion metal, an optional ohmic metal, or optional barrier metal are deposited beneath the conductive mechanical support metal. An advantage of metal contact to the backside of the III-nitride material layer is reduction and removal of thermal boundary resistance material layers such as removal of the AlN nucleation layer and the high_thermal conductivity of metals such as copper.

In at least one embodiment of the invention, it is desirable to singulate the wafer into die while attached to a dicing tape. In at least one embodiment of the invention, it is desirable to not have the metal in the kerf lanes to facilitate singulation while attached to the carrier substrate 120 or the dicing tape. In at least one embodiment of the invention, the conductive mechanical support metal on the backside of the III-nitride epitaxial material is removed or not formed in the kerf lanes to facilitate sawing, laser cutting or plasma dicing of the III-nitride epitaxial material. Methods of removing the conductive support metal from the kerf lanes include subtractive plasma etch, wet chemical etch, or selectively electroplating conductive mechanical support metal on the backside of the III-nitride epitaxial material using a seed metal and photodefining the electroplating area or electroless plating area. An advantage of metal contact to the backside of the III-nitride material layer is reduction and removal of thermal boundary resistance material layers such as removal of the AlN nucleation layer and the high_thermal conductivity of metals such as copper.

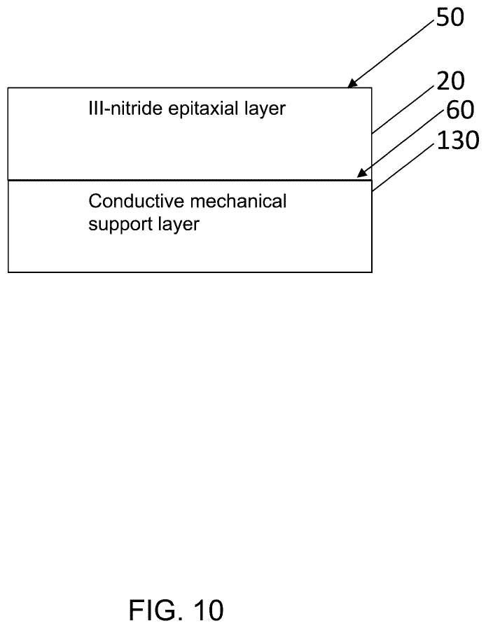

In at least one embodiment, the back surface of the III-nitride epitaxial material is temporary bonded (attached) to a dicing tape or permanently bonded to a second substrate, such as a silicon carbide substrate, a silicon substrate, a sapphire substrate, a polycrystalline diamond substrate, or a single-crystal diamond substrate. After attaching the backside of the III-nitride epitaxial material to a dicing tape, or wafer bonding to a silicon carbide substrate, a silicon substrate, a sapphire substrate, a polycrystalline diamond substrate, or a single crystal diamond substrate, the carrier substrate 120 is wafer-scale removed from the frontside 50 of the III-nitride epitaxial material 20, as indicated by way of illustration by the absence of the carrier substrate in FIG. 10.

Further Steps after Removing the Engineering Substrate and the Aluminum Nitride Nucleation Layer

Optionally, the method further includes the following steps:

The back surface of the III-nitride epitaxial layer is CMP polished to a surface roughness less than 1 nm, an optional phonon bridge layer is deposited, and the back surface (nitrogen polar surface) of the III-nitride epitaxial material wafer bonded to a diamond, silicon, or silicon carbide substrate.

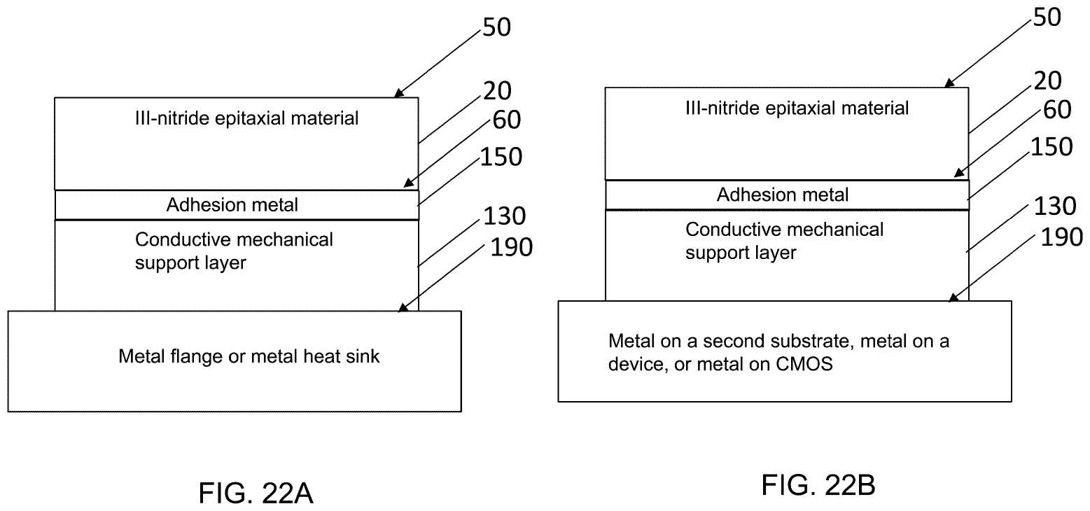

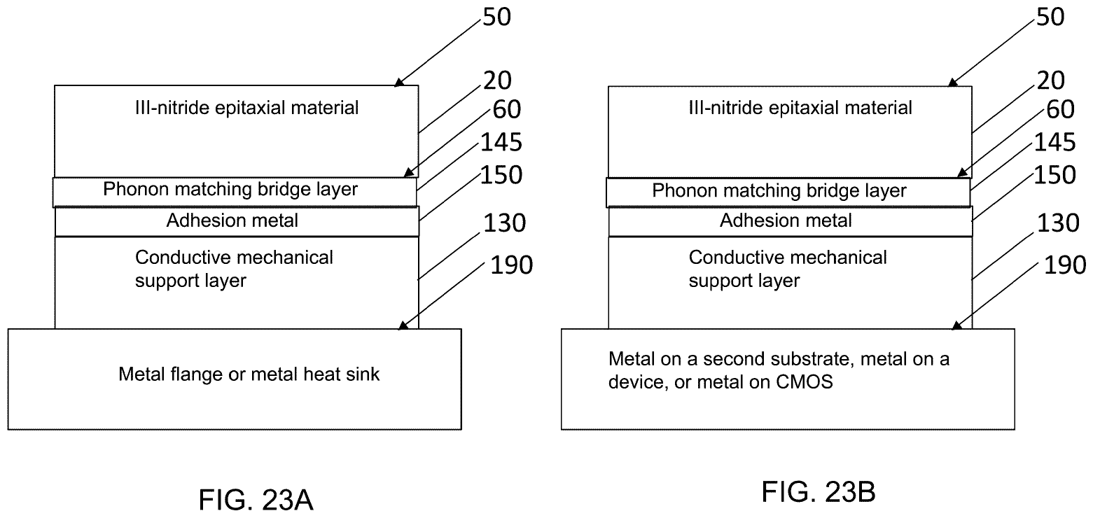

Alternately, an optional phonon bridge layer is deposited on the back surface of the III-nitride epitaxial material and an adhesion metal and a conductive metal support layer is wafer-scale formed on the back surface of the III-nitride epitaxial material, the metal is removed from kerf lanes or not formed in the kerf lanes, the metal surface is attached to a dicing tape, an organic protection layer is deposited, the III-nitride epitaxial material is singulated, the Known Good Die (KGD) can be optionally transferred to a tape frame to remove the organic protection layer, clean the die, and optionally plasma activate the die surface, the KGD can be picked from the tape frame or the dicing tape using a die-to-die bonding tool or a die-to-wafer bonding tool and solder bond, eutectic bonded, thermocompression bonded, fusion bond, or hybrid bonded to metal surface on a second substrate of the surface of a second substrate. The metal on a second substrate may be a metal flange for a RF transistor package or metal heat sink, as shown in FIG. 22A and FIG. 23A. FIG. 22B and FIG. 23B are cross-sectional views of metal on a second substrate or metal on a CMOS wafer for heterogeneous integration. FIG. 23B and FIG. 23B are cross-sectional views of a metal-to-metal bond with a standard phonon bridge layer at the interface of the III-nitride epitaxial material and the metal. The metal on the second surface is optionally polished for thermocompression bonding and eutectic bonding, may be CMP polished to a surface roughness less than 1 nm rms for fusion bonding, and may have a cap metal deposited on the metal. A dielectric surface and metal in a via may be CMP polished for hybrid bonding. For a solder connection, solder is deposited on one or both of the metal surfaces and a flux is used prior to bonding.

Alternately, an optional phonon bridge layer is deposited on the back surface of the III-nitride epitaxial layer, an adhesion metal and a conductive metal support layer is wafer-scale formed on the back surface of the III-nitride epitaxial material, the metal is removed from kerf lanes, III-nitride epitaxial material is singulated, a laser selectively illuminates the attach material to partially release the III-nitride epitaxial die, and the die picked from the carrier substrate 120 and is die-to-die or die-to-wafer solder, thermocompression, fusion, or hybrid bonded to metal surface on a second substrate or attached to a tape and cleaned or plasma activated. The metal on a second substrate may be a metal flange for a RF transistor package, a heat sink, metal on a second substrate, or metal on a CMOS wafer for heterogeneous integration. The metal on the second surface may be polished for thermocompression bonding and eutectic bonding, may be CMP polished to a surface roughness less than 1 nm rms for fusion bonding, and may have a cap metal deposited on the metal. For a solder connection, solder is deposited on one or both of the metal surfaces and a flux is used prior to bonding.

After the carrier substrate is removed, an embodiment of invention includes depositing an organic protection film on the surface of the III-nitride material and sawing, laser cutting, using photolithography and plasma dicing the III-nitride material mounted on a tape to singulate one or more III-nitride device dies or III-nitride film material so that one or more III-nitride device dies or III-nitride film material can be picked and placed using a die-to-die or die-to-wafer tool or transferred using a standard micro-transfer printing tool. In at least one embodiment, the III-nitride epitaxial die or III-nitride film material are transferred to a frame with an organic tape that will be used to remove the protection layer and clean the surface of the die to be attached a device or substrate. In at least one embodiment, the III-nitride epitaxial die or III-nitride film material are transferred to a frame with an organic tape that will be used to remove the protection layer, clean the surface of the die, and plasma activate the surface of the die for fusion bonding, direct interconnect bonding, or hybrid bonding to a device or III-nitride film. The die can be optionally flipped within the die-to-die bonder or die-to-wafer bonder or a flipping tool depending on whether face-to-face or face-to-back bonding is desired.

In at least one embodiment, the conductive metal material can be thermocompression bonded to a second metal such as a copper-to-copper thermocompression bond, a gold-to-gold thermocompression bond, a gold/tin to gold/tin eutectic compression bond, a copper/tin to copper/tin eutectic compression bond and other thermocompression bond. A standard cap material or passivation cap material 180 may be deposited on the conductive mechanical support metal layer 130 to facilitate metal-to-metal thermocompression bonding, as shown by way of illustration in FIG. 11. A standard, dicing tape 190 is attached directly to the conductive mechanical support metal layer 130 or indirectly thereto via the cap material 180, as shown by way of illustration in FIG. 11. The wafer is, for example, singulated while on the dicing tape. After the carrier substrate is removed, an embodiment of invention includes depositing an organic protection film on the surface of the three nitride material and sawing, laser cutting, using photolithography and plasma dicing the III-nitride material mounted on a tape to singulate one or more III-nitride device dies or III-nitride film material so that one or more III-nitride device dies or III-nitride film material can be picked and placed using a die-to-die or die-to-wafer tool or transferred using a standard micro-transfer printing toll. In at least one embodiment, the III-nitride epitaxial die or III-nitride film material are transferred to a frame with an organic tape that will be used to remove the protection layer and clean the surface of the die to be attached a device or substrate. In at least one embodiment, the III-nitride epitaxial die or III-nitride film material are transferred to a frame with an organic tape that will be used to remove the protection layer, clean the surface of the die, and plasma active the surface of the die for fusion bonding, direct interconnect bonding, or hybrid bonding to a device or substrate. The die can be optionally flipped within the die-to-die bonder or die-to-wafer bonder or a flipping tool depending on whether face-to-face or face-to-back bonding is desired.

In at least one embodiment, the conductive copper metal material can be fusion bonded to a second metal to form a copper-to-copper fusion bond or a copper-to-copper hybrid bond. A CMP polish is performed on the surface of the conductive metal material to a surface roughness less than 1 nm rms to enable metal-to-metal fusion bonding or metal to a dielectric/recessed copper in a via to enable hybrid bonding.

After the carrier substrate is removed, an embodiment of invention depositing an organic protection film on the surface of the three nitride material and sawing, laser cutting, using photolithography and plasma dicing the III-nitride material mounted on a tape to singulate one or more III-nitride device dies or III-nitride film material so that one or more III-nitride device dies or III-nitride film material can be picked and placed using a die-to-die or die-to-wafer tool or transferred using a standard micro-transfer printing tool. In at least one embodiment, the III-nitride epitaxial die or III-nitride film material are transferred to a frame with an organic tape that will be used to remove the protection layer and clean the surface of the die to be attached a device or substrate. In at least one embodiment, the III-nitride epitaxial die or III-nitride film material are transferred to a frame with an organic tape that will be used to remove the protection layer, clean the surface of the die, and plasma active the surface of the die for fusion bonding, direct interconnect bonding, or hybrid bonding to a device or substrate. The die can be optionally flipped within the die-to-die bonder or die-to-wafer bonder or a flipping tool depending on whether face-to-face or face-to-back bonding is desired.

In at least one embodiment, the GaN epitaxial material can be wafer scale fusion bonded to a polycrystalline diamond substrate or a single-crystalline diamond substrate 192, as shown by way of illustration in FIG. 18B. Optionally, the method further comprising includes the following steps. A standard, phonon bridge matching material layer 200 is deposited on the backside of the III-nitride epitaxial material 20, as shown by way of illustration in FIG. 12. An optional standard, silicon surface activation layer 210 is deposited on the polycrystalline diamond substrate, and activating the silicon surface activation layer via standard, surface-activated bonding or standard plasma activation and activating the exposed surface of the phonon bridge layer of the backside of the III-nitride layer and fusion bonding the III-nitride epitaxial layer to the polycrystalline diamond substrate or single-crystal diamond substrate.

The polycrystalline diamond substrate or single-crystal diamond substrate, for example, has a less than 1 nm rms surface roughness. Optionally, the polycrystalline diamond substrate or single-crystal diamond substrate is exposed to a NH₃/H₂O₂ solution to activate the polycrystalline diamond substrate. After activating the surfaces, the III-nitride epitaxial material with deposited phonon bridge layer is fusion bonded to the polycrystalline diamond or single-crystal diamond substrate.

### Removing the Engineered Substrate

Several methods of removal of the engineered substrate in a manner consistent with an embodiment of the invention are described as follows. These removal methods include the use of a grinding tolerance layer 220 formed within the engineer substrate 30, grinding into the top region of the non-crystalline substrate 40, grinding into a low trap sensitivity layer 230 formed within the III-nitride epitaxial material 20, or grinding into a III-nitride epitaxial material 20 with a thickness more than two microns in an embodiment, a thickness of more than four microns in an embodiment, a thickness of more than eight microns in an embodiment, a thickness of more than 15 microns in an embodiment, or thickness of more than 30 microns in an embodiment.

Grind into Grinding Tolerance Layer

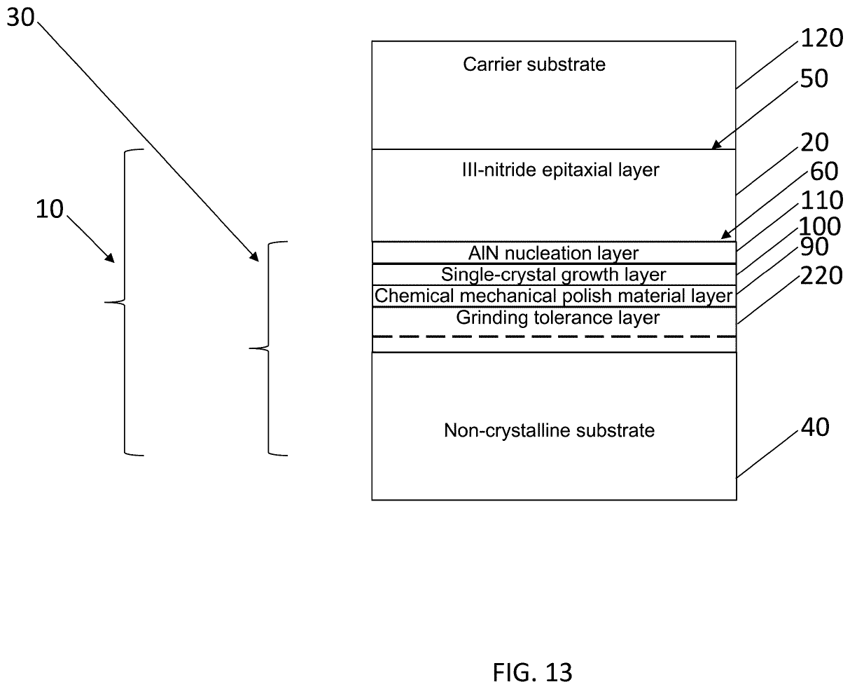

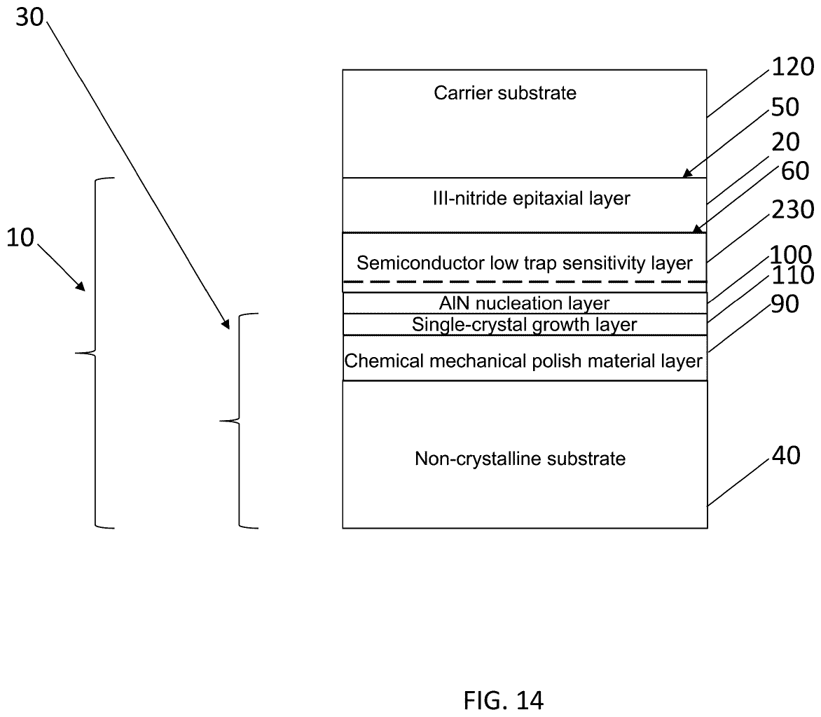

Optionally, the engineered substrate 30 comprises a grinding tolerance layer 220 between the non-crystalline substrate 40 and the top surface of the engineered substrate 30. The grinding tolerance layer 220 optionally includes polycrystalline silicon or SiO₂. In an embodiment of the invention, the grinding tolerance layer 220 has a thickness in a range of approximately 0.3 microns to approximately 4 microns. The engineered substrate 30 also includes a chemical mechanical polish material layer 90 abutting the grinding tolerance layer 220, the chemical mechanical polish material layer including, for example, polycrystalline silicon or SiO₂. The engineered substrate 30 additionally includes a standard, single crystal growth layer 100 abutting the chemical mechanical polish material layer 90. In at least one embodiment, the single crystal growth layer 100 or the chemical mechanical polish layer 90 may be a grinding tolerance layer 220. The engineered substrate 30 further includes an AlN nucleation layer 110 abutting the single crystal growth layer 90 and the III-nitride epitaxial material 20. The engineered substrate 30 is wafer-scale thinned to the grinding tolerance layer using rough grinding, fine grinding, and standard low damage grinding methods. Standard edge grinding can optionally be performed on the III-nitride on engineered substrate prior to backside grinding to reduce wafer breakage and edge the during backside grinding. In an embodiment of the invention, a portion of the grinding tolerance layer 220 remains after any grinding into this layer, as shown by way of illustration in FIG. 13. If such a portion of the grinding layer remains, then a standard chemical mechanical polishing, a standard polishing with a dry polishing pad, a standard plasma etching, and/or a standard chemical etching is optionally performed to remove the remaining grinding tolerance layer 220. The engineered substrate 30 is optionally further thinned removing the single-crystal growth layer, and/or the AlN nucleation layer is optionally removed from the III-nitride epitaxial layer, thereby exposing the III-nitride epitaxial material 20 free of grind damage. The CMP process and plasma etching processes is optionally chemically selective and thus etch stop processes is optionally used to selectively polish or etch one material layer without removing the material layer beneath the layer being polished or etched. The advantage of etch stop processes is that the etching and polishing is stopped enabling a uniform removable of material layers between the grinding layer and the GaN epitaxial substrate.

Optionally, the method includes the following steps. Optionally, the wafer-scale attaching the III-nitride epitaxial material 20 to the carrier substrate 120 includes one or more of the following steps. The III-nitride epitaxial material 20 is bonded in a standard manner to the carrier substrate 120. The III-nitride epitaxial material 20 is attached to the carrier substrate 120 using a standard, organic or inorganic attach material 140, as shown by way of illustration in FIG. 6. The III-nitride epitaxial layer is attached to the carrier substrate using a standard, heat-releasable polymer or UV-releasable polymer 150, as shown by way of illustration in FIG. 7. The III-nitride epitaxial layer is attached to the carrier substrate using a standard, laser-releasable layer 160, as shown by way of illustration in FIG. 8. The III-nitride epitaxial layer is attached to the carrier substrate using a standard, attach material 140, as shown by way of illustration in FIG. 11.

Optionally, the method after removing the engineered substrate 30 further includes the following steps. Three embodiments are disclosed by other embodiments are possible. The first embodiment is wafer-scale bonding the III-nitride epitaxial material to a polycrystalline diamond, a single-crystal diamond, or a silicon carbide substrate. The back surface of the III-nitride epitaxial material is CMP polished to a surface roughness less than 1 nm while attached to the carrier support, a phonon bridge layer is deposited, and the back surface of the III-nitride epitaxial material is fusion wafer bonded to a polycrystalline diamond, a single-crystal diamond, or a silicon carbide substrate.

The second embodiment is forming a conductive metal support layer on the backside of the III-nitride epitaxial layer, wafer scale removing the metal from the kerf lanes, wafer-scale transferring the metal surface to a dicing tape, singulate, optionally flip the die within the die-to-die or die-to-wafer tool and optionally pick and place the Known Good Die (KGD) on a tape frame to be cleaned and optionally plasma activated, optionally flip the die within the die-to-die or die-to-wafer tool, and then die-to-die or die-wafer solder bond, thermocompression bond, fusion bond, or hybrid bond to a metal surface on a second substrate.

The third embodiment is forming a conductive metal support layer on the backside of the III-nitride epitaxial layer, wafer scale removing the metal from the kerf lanes while attached to the carrier substrate, singulate while attached to the carrier substrate, selectively illuminate the LRL through a transparent carrier substrate to partially decompose the LRL to reduce the adhesive strength in selected lateral regions, pick the III-nitride epitaxial material or device die from the carrier substrate 120 optionally using a process of flipping the die within the die-to-die or die-to-wafer tool and optionally pick and place the Known Good Die (KGD) on a tape frame to be cleaned and optionally plasma activated, optionally flip the die within the die-to-die or die-to-wafer tool, and then die-to-die or die-wafer solder bond, thermocompression bond, fusion bond, or hybrid bond to a metal surface on a second substrate.

Additional details of the method include a standard cap material 180 is optionally deposited on the conductive mechanical support metal layer 130, as shown by way of illustration in FIG. 11. A standard, dicing tape 190 is attached directly to the conductive mechanical support metal layer 130 or indirectly thereto via the cap material 180, as shown by way of illustration in FIG. 11. The passivation metal layer 180, for example, includes NiCu, Pd, Ti, or Sn. The cap layer facilitates thermocompression or fusion bonding by reducing the oxidation of copper. In at least one embodiment, the conductive mechanical support metal 130 is solder bonded, thermocompression bonding, fusion bonded, or hybrid bonded to a metal layer or device having a metal or solder surface on a second substrate.

In at least one embodiment, the back surface of the III-nitride epitaxial material 20 is wafer bonded to a polycrystalline, single-crystal diamond substrate, a silicon substrate, a sapphire substrate, or a silicon carbide substrate 250, as shown by illustration in FIGS. 12, 18B, and 18C, producing III-nitride epitaxial material wafer bonded to a diamond substrate 250 or silicon carbide substrate 252 with a low thermal boundary resistance at the interface with a gallium polar surface available for device processing. Optionally, the method further comprising includes the following steps. The back surface of the III-nitride layer is CMP polished to a surface roughness of less than 1 nm. A standard, optional phonon bridge matching material layer 200 is wafer-scale deposited on the backside of the III-nitride epitaxial material 20 or on the front surface of the substrate 250, as shown by way of illustration in FIG. 12. A standard, silicon surface activation layer or metal activation layer 210 is optionally deposited on the polycrystalline diamond substrate or single-crystal diamond substrate 250, and a standard plasma activation is performed activating the silicon surface activation layer to facilitate wafer bonding. The wafer bonding may be performed in a vacuum. The wafer bonding may be performed at a temperature less than 200° C. The silicon surface activation layer can optionally be deposited on the surface of the phonon bridge matching layer 200 to facilitate fusion bonding. A silicon carbide or silicon substrate 250 can be directly bonded to the back surface of the III-nitride epitaxial layer or to the phonon bridge layer with or without the silicon surface activation layer. In at least one embodiment, the wafer is optionally flipped within the wafer bonding tool or a module connected to the wafer bonding tool and the gallium polar surface of the III-nitride epitaxial layer wafer bonded to the substrate 250 and an exposed nitrogen polar surface available for device processing, as shown by way of illustration in FIG. 21. Optionally, the silicon surface activation layer or metal activation 210 is deposited on a polycrystalline diamond substrate 250 or silicon carbide substrate 250. The polycrystalline diamond substrate, for example, has a less than 1 nm rms surface roughness. In at least one embodiment, the polycrystalline diamond substrate is exposed to a NH₃/H₂O₂ solution to activate the surface for wafer bonding.

Grind into Semiconductor Low Trap Electrical Sensitivity Layer

In another embodiment of the invention, the GaN engineered substrate is supported on the front side with a permanent bond to a second wafer optionally containing devices or a temporary bond to a standard, carrier substrate or a standard, polymer tape, and the GaN engineered substrate is ground from the backside with the grinding ending within a Semiconductor Low Trap Sensitivity Layer.

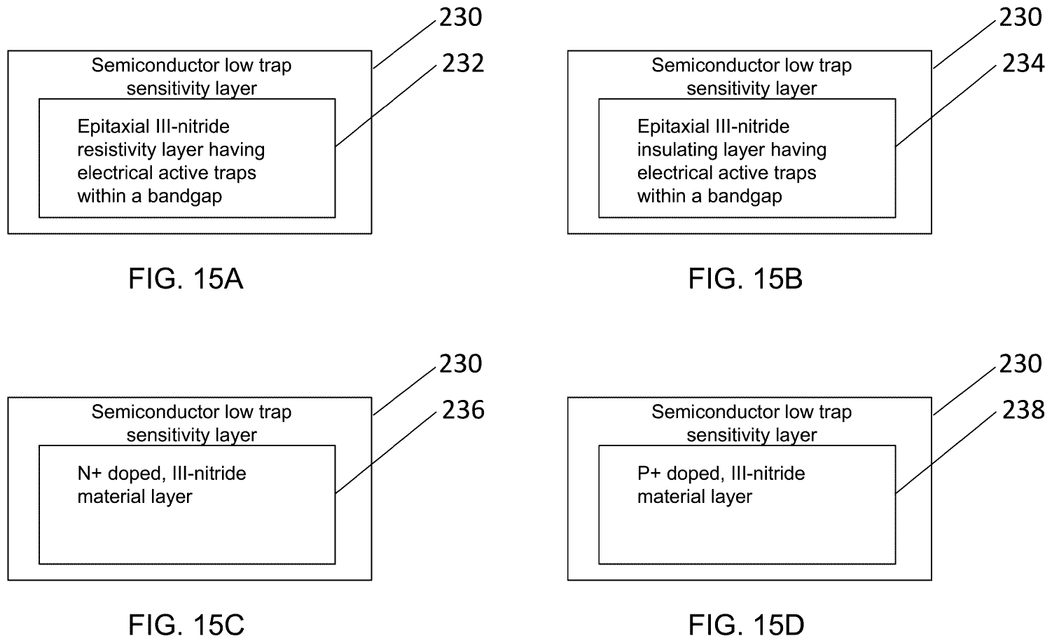

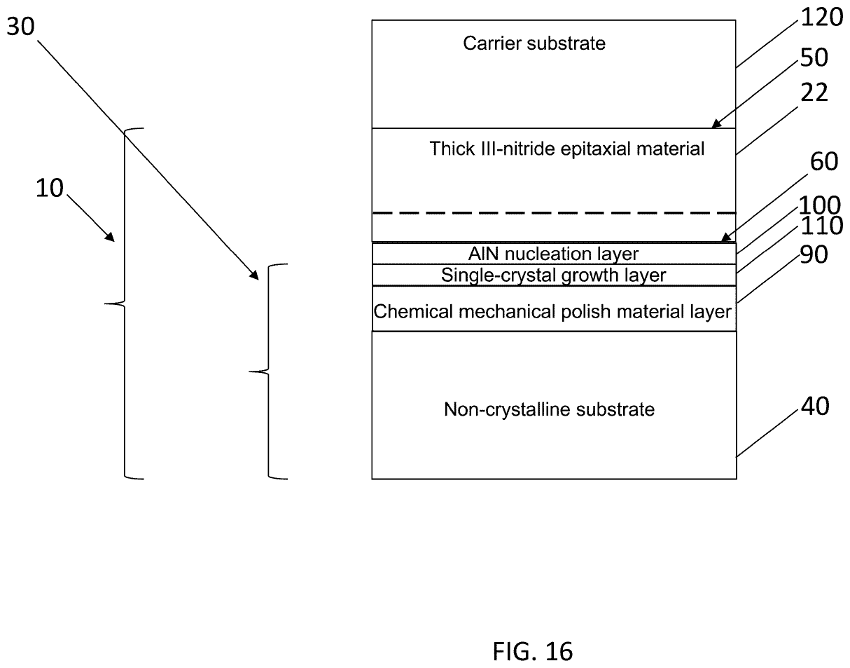

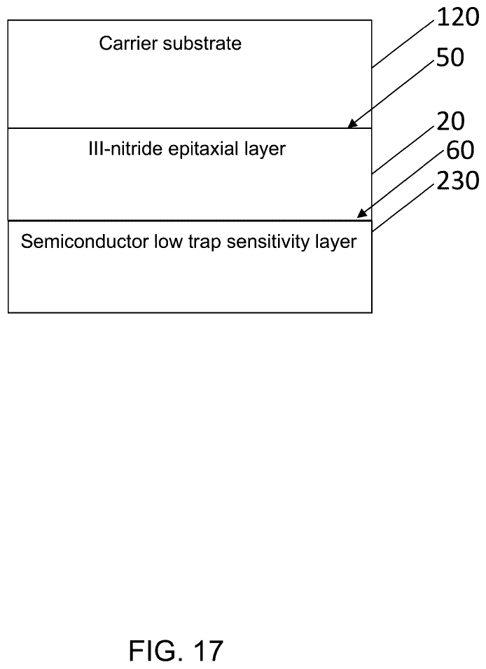

Optionally, the engineered substrate 30 includes a standard, chemical mechanical polish material layer 90 abutting the grinding tolerance layer 220, the chemical mechanical polish material layer including polycrystalline silicon or SiO₂. The engineered substrate 30 also includes a standard, single-crystal growth layer 100 abutting the chemical mechanical polish material layer 90. The engineered substrate 30 additionally includes an AlN nucleation layer 110 abutting the single-crystal growth layer 90. The III-nitride epitaxial material 20 further includes a standard, semiconductor low trap electrical sensitivity layer 230 abutting the AlN nucleation layer 110 and within the III-nitride epitaxial material 20. The semiconductor low trap electrical sensitivity layer 230 including a standard, epitaxial III-nitride resistivity layer including electrical active traps within a bandgap 232, a standard, III-nitride insulating layer including the electrical active traps within the bandgap 234, a standard, N+ doped III-nitride material layer 236, or a standard, P+ doped III-nitride material layer 238. In an embodiment of the invention, the semiconductor low trap sensitivity layer 230 has a thickness in the range between approximately 0.3 microns and approximately 99 microns. Optionally, the epitaxial III-nitride resistivity layer 232 includes standard, carbon impurities or standard, iron impurities. The III-nitride insulating layer 234 includes the carbon impurities or the iron impurities. Optionally, in an embodiment of the invention, a portion of the semiconductor low trap electrical sensitivity layer 230 remains after any grinding into this layer, as shown by way of illustration in FIG. 16. Standard edge grinding can optionally be performed on the III-nitride on engineered substrate prior to backside grinding to reduce wafer breakage and edge the during backside grinding. Optionally, in an embodiment of the invention shown in FIGS. 15A-15D, a thick III-nitride epitaxial material 22 has a thickness more than 2 microns, and removal of the engineered substrate includes removal of a lower region of the thick III-nitride epitaxial material. FIG. 17 is a cross-sectional view of a III-nitride epitaxial material attached to a wafer-scale support, optionally prior to removal thereof, and also attached to a remaining region of the III-nitride low trap sensitivity layer doped with carbon or iron.

Fine grinding and low damage grinding approaches according to an embodiment of the invention, for example, yield a maximum subsurface damage depth less than 1 micron. Thus, for Low Trap Electrical Sensitivity Layer thicker than approximately 2 microns, the subsurface damage can be within the Low Trap Sensitivity Layer and there will not be grinding damage in the GaN epitaxial layers beyond the Semiconductor Low Trap Sensitivity Layer. An advantage of this approach is that there is no grinding damage in the III-nitride epitaxial layer beyond the Semiconductor Law Trap Sensitivity Layer.

Optionally, the method further includes the following steps.

The back surface of the III-nitride epitaxial layer is CMP polished to a surface roughness less than 1 nm, a phonon bridge layer is deposited, and is wafer bonded to a diamond or silicon carbide substrate. Alternately, a conductive metal support layer is wafer-scale deposited on the back surface of the III-nitride epitaxial material, the metal is removed from kerf lanes, and the metal surface is attached to a dicing tape and the die is die-to-die or die-to-wafer solder, thermocompression, fusion, or hybrid bonded to metal surface on a second substrate. Alternately, a conductive metal support layer is wafer-scale deposited on the back surface of the III-nitride epitaxial material, the metal is removed from kerf lanes, III-nitride epitaxial material is singulated, a laser selectively illuminates the attach material to partially release the III-nitride epitaxial die, and the die picked from the carrier substrate 120 and is die-to-die or die-to-wafer solder, thermocompression, fusion, or hybrid bonded to metal surface on a second substrate or attached to a tape and cleaned or plasma activated.

Additional details of the method include a standard cap material 180 is optionally deposited on the conductive mechanical support metal layer 130, as shown by way of illustration in FIG. 11. A standard, dicing tape 190 is attached directly to the conductive mechanical support metal layer 130 or indirectly thereto via the cap material 180, as shown by way of illustration in FIG. 11. The passivation metal layer 180, for example, includes NiCu, Pd, Ti, or Sn. The cap layer facilitates thermocompression or fusion bonding by reducing the oxidation of copper. In at least one embodiment, the conductive mechanical support metal 130 is solder bonded, thermocompression bonding, fusion bonded, or hybrid bonded to a metal layer or device having a metal or solder surface on a second substrate.

In at least one embodiment, the back surface of the III-nitride epitaxial material 20 is wafer bonded to a polycrystalline, single crystal diamond substrate or a silicon carbide substrate 250, as shown by illustration in FIG. 12, producing III-nitride epitaxial material wafer bonded to a diamond or silicon carbide substrate 250 with a low thermal boundary resistance at the interface with a gallium polar surface available for device processing. Optionally, the method further comprising includes the following steps. The back surface of the III-nitride layer is CMP polished to a surface roughness of less than 1 nm. A standard, phonon bridge matching material layer 200 is wafer-scale deposited on the backside of the III-nitride epitaxial material 20 or on the front surface of the substrate 250, as shown by way of illustration in FIG. 12. A standard, silicon surface activation layer or metal activation layer 210 is optionally deposited on the phonon bridge matching material layer 200, and a standard plasma activation is performed activating the silicon surface activation layer to facilitate wafer bonding. The wafer bonding may be performed in a vacuum. In at least one embodiment, the wafer is optionally flipped within the wafer bonding tool or a module connected to the wafer bonding tool and the gallium polar surface of the III-nitride epitaxial layer wafer bonded to the substrate 250 and an exposed nitrogen polar surface available for device processing. Optionally, the silicon surface activation layer or metal activation 210 is deposited on a polycrystalline diamond substrate 250 or silicon carbide substrate 250. The polycrystalline diamond substrate, for example, has a less than 1 nm rms surface roughness. In at least one embodiment, the polycrystalline diamond substrate is exposed to a NH₃/H₂O₂ solution to activate the surface for wafer bonding.

Grind into Top Region of Non-Crystalline Substrate

In another embodiment of the invention, the III-nitride on engineered substrate is supported on the front side with a permanent bond to a second wafer optionally containing devices or a temporary bond to a standard, carrier substrate or a standard, polymer tape, and the III-nitride on engineered substrate is ground from the backside with the grinding ending within the top region of the non-crystalline substrate.

In an embodiment of the invention, the GaN engineered substrate is supported on the front side with a permanent bond to a second wafer optionally containing devices or a temporary bond to a standard, carrier substrate or a standard, polymer tape, and the GaN engineered substrate is ground from the backside with the grinding ending within approximately less than 5 microns of the first surface (upper region 240) of the non-crystalline substrate. Standard edge grinding can optionally be performed on the III-nitride on engineered substrate prior to backside grinding to reduce wafer breakage and edge the during backside grinding. The method of thinning the non-crystalline substrate from the backside include rough grinding, fine grinding, standard low damage grinding, Chemical Mechanical Polishing (“CMP”), polishing using dry polish pad, plasma etching, chemical etching, or ion beam etching. Additional etching or polishing steps are performed to etch or polish through the remaining portion of the upper region of the non-crystalline substrate, a silicon (111) material layer, an AlN nucleation layer, and other optional material layers such as silicon oxide (SiO₂) layer, silicon nitride (Si₃N₄) layer, metal oxide layer, metal nitride layer, or metal layer. The CMP process and plasma etching processes can be chemically selective and thus etch stop processes can be used to selectively polish or etch one material layer without removing the material layer beneath the layer being polished or etched. The advantage of etch stop processes is that the etching and polishing is stopped enabling a uniform removable of material layers between the grinding layer and the GaN epitaxial substrate. An advantage of this approach is that there is no grinding damage in the III-nitride epitaxial layer. The CMP process and plasma etching processes can be chemically selective and thus etch stop processes can be used to selectively polish or etch one material layer without removing the material layer beneath the layer being polished or etched. The advantage of etch stop processes is that the etching and polishing is stopped enabling a uniform removable of material layers between the grinding layer and the GaN epitaxial substrate.

In an embodiment of the invention, a GaN engineered substrate includes a non-crystalline substrate, a material whose first surface is optionally polished by chemical mechanical polishing (CMP) to a surface roughness less than approximately 1 nm RMS, a signal crystal growth layer which is typically a silicon layer having a (111) orientation, an aluminum nitride nucleation layer grown on a single crystal growth layer, and a single-crystal III-nitride epitaxial layer. The coefficient of thermal expansion of the non-crystalline substrate is typically matched to the coefficient of thermal expansion of the single crystal III-nitride epitaxial layer. The coefficient of thermal expansion of the non-crystalline substrate is typically matched to the coefficient of thermal expansion of the single-crystal GaN epitaxial layer with less than 20 percent mismatch in the thermal coefficient of expansions. In at least one embodiment of the invention, the semiconductor single-crystal epitaxial layer single-crystal III-nitride epitaxial layers, a silicon carbide epitaxial layer, or a gallium oxide epitaxial layer.

Grind into a Thick III-Nitride Epitaxial Material

The III-nitride epitaxial material 20 is thermal expansion matched to the engineered substrate 30 allowing a thick III-nitride epitaxial layer to be grown without cracking. In at least one embodiment, a III-nitride epitaxial material 20 thicker than 2 microns can be grown on the engineered substrate 30 without the III-nitride epitaxial layer cracking. In at least one embodiment, a III-nitride epitaxial material 20 thicker than 4 microns can be grown on the engineered substrate 30 without the III-nitride epitaxial layer cracking. In at least one embodiment, a III-nitride epitaxial material 20 thicker than 8 microns can be grown on the engineered substrate 30 without the III-nitride epitaxial layer cracking. In at least one embodiment, a III-nitride epitaxial material 20 thicker than 15 microns can be grown on the engineered substrate 30 without the III-nitride epitaxial layer cracking. In at least one embodiment, a III-nitride epitaxial material 20 thicker than 30 microns can be grown on the engineered substrate 30 without the III-nitride epitaxial layer cracking. In at least one embodiment, a III-nitride epitaxial material 20 thicker than 60 microns can be grown on the engineered substrate 30 without the III-nitride epitaxial layer cracking. In at least one embodiment, the III-nitride epitaxial material is grown to a thickness in the range of 2 microns to 200 microns.

Optionally, the engineered substrate 30 includes a standard, chemical mechanical polish material layer 90 abutting the grinding tolerance layer 220, the chemical mechanical polish material layer including polycrystalline silicon or SiO₂. The engineered substrate 30 also includes a standard, silicon (111) layer 100 abutting the chemical mechanical polish material layer 90. The engineered substrate 30 additionally includes an AlN nucleation layer 110 abutting the silicon (111) layer 90. The III-nitride epitaxial material 20 further is grown to a thickness in the range of 2 microns to 200 microns includes abutting the AlN nucleation layer 110 and the III-nitride epitaxial material 20. Optionally, in an embodiment of the invention, a portion of the III-nitride epitaxial material remains after any grinding into this material layer, as shown by way of illustration in FIG. 16.

The engineered substrate is removed using the method of grinding into a III-nitride epitaxial material with a thickness more than 2 microns. The method of grinding includes rough grinding followed by fine grinding and/or low damage grinding. The method of thinning further includes steps of chemical mechanical polishing, polishing with a dry polishing pad, plasma etching, or chemical etching. Standard edge grinding is optionally performed on the III-nitride on engineered substrate prior to backside grinding to reduce wafer breakage and edge the during backside grinding.

Optionally, the method further includes the following steps. The back surface of the III-nitride epitaxial layer is CMP polished to a surface roughness less than 1 nm, a phonon bridge layer is deposited, and is wafer bonded to a diamond or silicon carbide substrate. Alternately, a conductive metal support layer is wafer-scale deposited on the back surface of the III-nitride epitaxial material, the metal is removed from kerf lanes, and the metal surface is attached to a dicing tape and the die is die-to-die or die-to-wafer solder, thermocompression, fusion, or hybrid bonded to metal surface on a second substrate. Alternately, a conductive metal support layer is wafer-scale deposited on the back surface of the III-nitride epitaxial material, the metal is removed from kerf lanes, III-nitride epitaxial material is singulated, a laser selectively illuminates the attach material to partially release the III-nitride epitaxial die, and the die picked from the carrier substrate 120 and is die-to-die or die-to-wafer solder, thermocompression, fusion, or hybrid bonded to metal surface on a second substrate or attached to a tape and cleaned or plasma activated.

Additional details of the method include a standard cap material 180 is optionally deposited on the conductive mechanical support metal layer 130, as shown by way of illustration in FIG. 11. A standard, dicing tape 190 is attached directly to the conductive mechanical support metal layer 130 or indirectly thereto via the cap material 180, as shown by way of illustration in FIG. 11. The passivation metal layer 180, for example, includes NiCu, Pd, Ti, or Sn. The cap layer facilitates thermocompression or fusion bonding by reducing the oxidation of copper. In at least one embodiment, the conductive mechanical support metal 130 is solder bonded, thermocompression bonding, fusion bonded, or hybrid bonded to a metal layer or device having a metal or solder surface on a second substrate.

In at least one embodiment, the back surface of the III-nitride epitaxial material 20 is wafer bonded to a polycrystalline, single crystal diamond substrate, a silicon substrate, a sapphire substrate, or a silicon carbide substrate 250, as shown by illustration in FIG. 12, producing III-nitride epitaxial material wafer bonded to a diamond or silicon carbide substrate 250 with a low thermal boundary resistance at the interface with a gallium polar surface available for device processing. Optionally, the method further comprising includes the following steps. The back surface of the III-nitride layer is CMP polished to a surface roughness of less than 1 nm. A standard, phonon bridge matching material layer 200 is wafer-scale deposited on the backside of the III-nitride epitaxial material 20 or on the front surface of the substrate 250, as shown by way of illustration in FIG. 12. A standard, silicon surface activation layer or metal activation layer 210 is optionally deposited on the phonon bridge matching material layer 200, and a standard plasma activation is performed activating the silicon surface activation layer to facilitate wafer bonding. The wafer bonding may be performed in a vacuum. In at least one embodiment, the wafer can be flipped within the wafer bonding tool or a module connected to the wafer bonding tool and the gallium polar surface of the III-nitride epitaxial layer wafer bonded to the substrate 250 and an exposed nitrogen polar surface available for device processing. Optionally, the silicon surface activation layer or metal activation 210 is deposited on a polycrystalline diamond substrate 250 or silicon carbide substrate 250. The polycrystalline diamond substrate, for example, has a less than 1 nm rms surface roughness. In at least one embodiment, the substrate 250 is exposed to a NH₃/H₂O₂ solution to activate the diamond surface for wafer bonding.

Following the rough grinding, fine grinding, and low damage grinding, a number of process steps can be performed. Optional backside processing on III-nitride second surface can be performed such as CMP of the III-nitride material, thinning III-nitride material, wafer bonding so a substrate such as diamond, silicon carbide, or gallium oxide, chemical etch or plasma etch III-nitride material, ion implant doping within the into second surface of III-nitride material, deposition of ohmic metal, laser annealing to activate ion implanted dopant, laser annealing to improve metal ohmic contacts, photolithography, metal deposition, CMP of a metal to make a low surface roughness metal, deposition of an oxidation resistant cap material on metal, deposition of a metal seed layer, electroplating metal for mechanical support, electroplating solder, depositing solder material, sawing or laser cutting to singulate die, electrodischarge machining through metal to singulate dice, and other process steps

Further processing steps are optionally performed to fabricate device such as:
1. A wafer scale non-grind damaged GaN device wafer or GaN epitaxial material fusion wafer bonded to a polycrystalline diamond substrate or polycrystalline diamond composite substrate having phonon bridge matching layers at the bond interface and optionally having deposited silicon material layers on the diamond surface, optionally having OH-species on the diamond surface, optionally having silicon on the diamond surface, optionally having OH-species on the GaN second surface and using surface activated bonding (SAB) with argon ion irradiation or plasma activation with nitrogen or oxygen exposures of the surface prior to wafer bonding to increase wafer bond strength. For example, in an embodiment of the invention, to activate the diamond surface for wafer bonding. a silicon layer is deposited on diamond and the silicon layer is activated. As another example, in an embodiment of the invention, to activate the diamond surface for wafer bonding, a NaOH solution is applied to the diamond surface.
2. A thin non-grind damaged GaN device die fabricated having sufficient mechanical strength for pick and place bonding, die-to-die bonding, die-to-wafer bonding, microprint transfer bonding, thermocompression boning, or hybrid bonding.
3. A copper-to-copper bonding
4. A wafer scale hybrid bonding or thermocompression bonding.
5. A back-to-face wafer-to-wafer bonding and die-to-wafer bonding.
6. A face-to-face wafer-to-wafer bonding and die-to-wafer bonding.
7. A composite copper substrate fabricated on the backside of the non-grind damaged GaN wafer having phonon bridge matching layers at the bond interface.
8. A wafer scale non-grind damaged GaN device or GaN epitaxial material fusion wafer bonded to silicon carbide or silicon substrate.
9. A non-grind damage III-nitride RF device having copper backside electrode and forming a microstrip transmission layer.
10. A front surface of a GaN engineered substrate having lasers permanently wafer bonded face-to-face to a lithium niobate substrate have electro-optic modulators and optical waveguides.
11. A GaN Engineered substrate with devices permanently wafer bonded face-to-face to a CMOS wafer.
12. Vertical non-grind damaged GaN power devices.

The method of separation comprises either permanently bonding the front side of a GaN engineered substrate optionally having GaN device to a second substrate optionally having devices or temporary bonding the front side of a GaN engineered substrate to a standard, carrier substrate or a standard tape, and thinning the GaN engineered substrate from the backside using rough grinding, fine grinding, CMP, polishing using dry polish pad, plasma etch, or ion beam thinning.

For the permanently bonded embodiment, the second wafer can be a wafer having CMOS devices, indium phosphide devices, integrated photonics, optical waveguides, electrical transmission lines, power switching devices, lasers, light emitting devices, thermally enhanced flip chip bonding structures, and other device types. The GaN device wafer and second wafers will be face-to-face bonded. Example of approaches that can be used include fusion bonding, hybrid bonding which can include both dielectric-to-dielectric bonding and copper-to-copper bonding, fluxless copper-to-copper thermocompression bonding, eutectic bonding, or solder microbump bonding. The approach of bonding the GaN device wafer to the second wafer is known to those of ordinary skill in the art.

### Carrier Substrate

For accurate grinding, it is preferable that the second wafer and the carrier substrate and the attach material that adheres the carrier substrate to the GaN Engineered substrate have low total thickness variation. The carrier substrate includes, for example, a standard glass substrate, a standard sapphire substrate, a standard quartz substrate, a standard silicon substrate, a standard silicon carbide substrate, a polycrystalline diamond substrate, or a single-crystal diamond substrate. In at least one embodiment of the invention, the carrier substrate has a total thickness variation less than 5 microns. In at least one embodiment of the invention, the carrier substrate has low total thickness variation to improve the accuracy of the grinding process. In at least one embodiment of the invention, the carrier substrate has a total thickness variation less than 2 microns. In at least one embodiment of the invention, the carrier substrate has a total thickness variation less than 1 microns. In at least one embodiment of the invention, the carrier substrate has a total thickness variation less than 0.5 microns. The wafer carrier substrate is, for example, transparent to laser wavelengths used to implement laser release of a polymer layer or inorganic layer from the wafer carrier substrate to implement laser release of the wafer carrier substrate from the III-nitride epitaxial layer. The carrier substrate can be transparent for selected wavelength used to ablate attach material or create hydrogen or bubbles in the material at the interface of the carrier substrate second surface and the attach material to reduce the adhesion of attach material to the carrier substrate to allow removal of the carrier substrate. Infrared wavelengths are typically used to illuminate through a silicon substrate. Ultraviolet (“UV”) wavelengths can be used with glass, sapphire, or quartz substrate.

Attach Material that Adheres the Carrier Substrate to the III-Nitride on Engineered Substrate

The attach material will typically be an organic material but can also be an inorganic material and can be a combination of an organic material and an inorganic material. In at least one embodiment of the invention, the material can be high temperature compatible attach material. In at least one embodiment of the invention, the attach material can be exposed to a temperature of 250° C. and can be removable after 250° C. exposures. In at least one embodiment of the invention, the attach material can be exposed to a temperature of 300° C. and can be removable after 300° C. exposures. In at least one embodiment of the invention, an inorganic attach material can be exposed to a temperature of 1000° C. and can be removed after 1000° C. A high temperature compatible attach material is desirable if solder is deposited on solderable metal on the backside of the thinned GaN epitaxial layer after thinning and polishing. The attach material can comprise a Laser Releasable Layer (“LRL”) material that is adhered to the second surface of the carrier substrate.

The surface of the polymer layer or inorganic layer attach material can be polished to reduce the surface roughness and surface topography of the polymer or inorganic layer. The surface topography of the polymer layer or inorganic layer can be reduced to less than approximately 0.2 microns and the surface roughness reduced to less than approximately 1 nm RMS.

GaN single-crystal epitaxial layer having multiple resistivity layers can also be desirable for vertical GaN power devices. A vertical GaN power device can have a lower resistivity layer less than approximately 500 ohm-cm (N+ drain region) and an upper resistivity layer of more than approximately 1000 ohm-cm (N-type drift layer). The N+ layer can be considered an electrically dead region.

### Phonon Matching Intermediate Bridge Layer Between the Second Surface

A photon matching intermediate bridge layer is optionally deposited on the second surface (back surface) of the III-nitride epitaxial material to improve the heat transfer from the III-nitride epitaxial material into a metal layer, a silicon carbide substrate, a polycrystalline diamond substrate, or a single-crystal diamond substrate. The phonon matching intermediate bridge layer optionally includes silicon nitride, silicon carbide, aluminum nitride, boron phosphide, boron carbide, or aluminum phosphide layer. The phonon matching intermediate bridge layer thickness is approximately 2 nm to 3 nm thick.

One of ordinary skill in the art will readily appreciate that there can be many embodiment variations. Although exemplary embodiments of the present invention and their advantages have been described in detail, it should be understood that various changes, substitutions and alterations can be made herein without departing from the spirit and scope defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure herein, processes, machines, manufacture, compositions of matter, means, methods, or steps, presently existing or later to be developed, that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. A method comprising:
providing a III-nitride-on-engineered substrate, the III-nitride-on-engineered substrate comprising a III-nitride epitaxial material, the III-nitride epitaxial material comprising a frontside, a backside, and a III-nitride epitaxial region free of grind damage, the III-nitride-on-engineered substrate comprising an engineered substrate on the backside of the III-nitride epitaxial material, the engineered substrate comprising a non-crystalline substrate;
wafer-scale removing, from the backside of the III-nitride epitaxial material, the engineered substrate, thereby exposing III-nitride epitaxial material comprising a the III-nitride epitaxial region free of grind damage.

2. The method of claim 1, wherein said wafer-scale removing the engineered substrate comprises:
attaching the frontside to a carrier substrate; and
at least one of rough grinding, fine grinding, low damage grinding, chemical mechanical polishing, dry polishing, wet etching, plasma etching, and ion milling the engineered substrate.

4. The method of claim 2, wherein the engineered substrate comprises a single-crystal growth material layer, a chemical mechanical polish layer, and an aluminum nitride nucleation layer,
wherein the non-crystalline substrate comprises a top region,
wherein the method of removing the engineered substrate comprises at least one of:
attaching the frontside to the carrier substrate;
grinding to within the top region of the non-crystalline substrate;
removing a remainder of the non-crystalline substrate;
removing a chemical mechanical polish layer;
removing a single crystal growth material layer; and
removing the aluminum nitride nucleation layer.

5. The method of claim 2, wherein said at least one of rough grinding, fine grinding, low damage grinding, chemical mechanical polishing, dry polishing, wet etching, plasma etching, and ion milling the engineered substrate comprises:
grinding to within the III-nitride epitaxial material.

6. The method according to claim 2, wherein the engineered substrate comprises a low sensitivity trap layer,
wherein said removing the engineered substrate comprises:
grinding to within the low sensitivity trap layer.

7. The method according to claim 2, wherein the engineered substrate comprises a grinding tolerance layer, a chemical mechanical polish layer, a single-crystal growth material layer, and an aluminum nitride nucleation layer,
wherein said removing the engineered substrate comprises at least one of:
grinding to within the grinding tolerance layer;
removing the chemical mechanical polish layer;
removing single-crystal growth material layer; and
removing the aluminum nitride nucleation layer.

8. The method according to claim 2, wherein the III-nitride epitaxial material comprising a threading dislocation density less than at least 10⁹ cm⁻².

9. The method according to claim 1, wherein the non-crystalline substrate comprises one of a polycrystalline substrate and a ceramic substrate.

10. The method according to claim 1, wherein said removing, from the backside of the III-nitride epitaxial material, the engineered substrate comprises at least one of:
wafer-scale grinding the engineered substrate;
wafer-scale chemical etching the engineered substrate;
wafer-scale chemical mechanical polishing the engineered substrate;
wafer-scale plasma etching the engineered substrate;
wafer-scale grinding the III-nitride epitaxial material; and
wafer-scale chemical mechanical polishing the III-nitride epitaxial material.

11. The method according to claim 2, wherein the III-nitride epitaxial material comprises at least one die,
wherein the method further comprises at least one of:
supporting, using the carrier substrate, the frontside of the III-nitride epitaxial material;
removing the engineered substrate;
depositing a conductive mechanical support metal layer on the backside of the III-nitride epitaxial material, the conductive mechanical support metal layer comprising at least one of copper, gold, and molybdenum;
attaching the conductive mechanical support metal layer surface to a tape,
removing the carrier substrate from the III-nitride epitaxial material; and
singulating the at least one die from the III-nitride epitaxial material.

12. The method according to claim 2, wherein said attaching the III-nitride epitaxial material to the carrier substrate comprises at least one of:
bonding the III-nitride epitaxial material to the carrier substrate;
attaching the III-nitride epitaxial material to the carrier substrate using an attach material, the attach material comprising at least one of an organic attach material, an inorganic attach material, and a laser-releasable layer;
attaching the III-nitride epitaxial material to the carrier substrate using a heat releasable organic material; and
attaching the III-nitride epitaxial material to the carrier substrate using a UV-releasable organic material.

13. The method according to claim 12, further comprises:
depositing the conductive mechanical support metal layer on the back surface of the III-nitride material; and
performing one of a metal-to-metal thermocompression bond, a metal-to-metal fusion bond, and a hybrid bond to a metal surface on a second substrate.

14. The method according to claim 13, further comprising at least one of:
depositing a phonon bridge matching material layer on the backside of the III-nitride epitaxial material.

15. The method according to claim 1, wherein the engineered substrate comprises:
a grinding tolerance layer abutting the non-crystalline substrate, the grinding tolerance layer comprising one of silicon, silicon carbide, polycrystalline silicon, and SiO₂;
a chemical mechanical polish material layer abutting the grinding tolerance layer, the chemical mechanical polish material layer comprising one of polycrystalline silicon and SiO₂;
a single-crystal growth layer abutting the chemical mechanical polish material layer; and
an AlN nucleation layer abutting the single-crystal growth layer and the III-nitride epitaxial material,
wherein the method further comprises at least one of:
grinding to within the grinding tolerance layer;
removing the chemical mechanical polish material layer; and
removing the aluminum nitride nucleation layer.

16. The method according to claim 1, wherein the III-nitride epitaxial material comprises a nitrogen polar surface,
wherein the method further comprises:
permanent bonding the metal polar surface of the III-nitride epitaxial material to the carrier substrate;
exposing a nitrogen polar surface of the III-nitride material; and
polishing the exposed nitrogen polar surface.

17. The method according to claim 1, wherein the III-nitride epitaxial material comprises a nitrogen polar surface,
wherein the method further comprises:
temporarily bonding the metal polar surface of the III-nitride epitaxial layer to a carrier substrate;
removing the engineer substrate and the aluminum nitride nucleation layer exposing a nitrogen polar surface of the III-nitride material;
wafer-scale flipping the III-nitride epitaxial material within the wafer bonding tool;
permanently bonding the exposed metal polar surface of the III-epitaxial layer to the carrier substrate;
removing a temporarily bonded carrier substrate on the nitrogen polar surface,
thereby leaving an exposed nitrogen polar surface; and
polishing the exposed nitrogen polar surface.

18. The method of claim 2, wherein the III-nitride epitaxial material comprises a metal polar surface,
wherein the method further comprises:
depositing a phonon bridge material layer between the carrier substrate and the metal polar surface of the III-nitride epitaxial material.

19. The method of claim 2, wherein the III-nitride epitaxial material comprises a nitrogen polar surface,
wherein the method further comprises:
depositing a phonon bridge material layer between the carrier substrate and the nitrogen polar surface of the III-nitride epitaxial material.

20. The method according to claim 19, further comprising at least one of:
depositing a silicon surface activation layer on a diamond substrate, and activating the silicon surface activation layer via one of surface-activated bonding and plasma activation; and
exposing the diamond carrier substrate to a NH₃/H₂O₂ solution to activate the diamond substrate surface.

21. The method according to claim 1, wherein the engineered substrate comprises:
a chemical mechanical polish material layer abutting the grinding tolerance layer, the chemical mechanical polish material layer comprising one of polycrystalline silicon and SiO₂;
a silicon (111) layer abutting the chemical mechanical polish material layer;
an AlN nucleation layer abutting the silicon (111) layer; and
a semiconductor low trap electrical sensitivity layer abutting the AlN nucleation layer and the III-nitride epitaxial material, the semiconductor low trap electrical sensitivity layer comprising one of an epitaxial III-nitride resistivity layer including electrical active traps within a bandgap, a III-nitride insulating layer including the electrical active traps within the bandgap, an N+ doped III-nitride material layer, and a P+ doped III-nitride material layer.

22. The method according to claim 21, wherein the epitaxial III-nitride resistivity layer comprises one of carbon impurities and iron impurities,
wherein the III-nitride insulating layer comprises one of the carbon impurities and the iron impurities.

23. A device comprising:
a III-nitride epitaxial layer; and
an engineering substrate abutting said III-nitride epitaxial layer, said engineering substrate comprising:
an AlN nucleation layer abutting said III-nitride epitaxial layer; and
a grinding tolerance layer abutting said AlN nucleation layer, said grinding tolerance layer comprising at least one of:
a single-crystal growth layer; and
a chemical mechanical polish layer.

24. A device comprising:
a III-nitride epitaxial layer comprising:
an exposed nitrogen polar surface; and
a metal polar surface; and
one of a diamond substrate and a silicon carbide substrate permanently bonded, one of directly and indirectly, to said metal polar surface of the III-nitride epitaxial layer.

25. The device according to claim 24, further comprising:
a phonon matching bridge layer intermediating said III-nitride epitaxial layer and said one of said diamond substrate and said silicon carbide substrate
